(19) United States
(12) Patent Application Publication
(10) Pub. No.: US 2019/0115718 A1
(43) Pub. Date: Apr. 18, 2019

(54) EYE-SAFE LIGHT SOURCE AND METHOD FOR MANUFACTURING SAME

(71) Applicant: SHARP KABUSHIKI KAISHA, Sakai City, Osaka (JP)

(72) Inventor: SHIN ITOH, Sakai City (JP)

(21) Appl. No.: 16/090,257

(22) PCT Filed: Mar. 15, 2017
(86) PCT No.: PCT/JP2017/010366

§ 371 Date: Sep. 30, 2018

(30) Foreign Application Priority Data
Mar. 31, 2016 (JP) 2016-072904

(51) Int. Cl. H01S 5/022; H01S 5/028

(52) U.S. Cl. CPC H01S 5/02244; H01S 5/028; H01S 5/02228

(57) ABSTRACT

An eye-safe light source that has a long lifetime and includes a lid which is not easily separated from a container is implemented. A transparent resin layer that seals a semiconductor laser fixes a cover to a package. A recess part that includes a bottom surface on which the semiconductor laser is mounted, a reflective surface on which laser light is reflected, and an opening through which the reflected laser light is radiated is disposed in the package. The cover covers the opening, and the transparent resin layer is disposed in the recess part.

### TECHNICAL FIELD

The present invention relates to an eye-safe light source that is made eye-safe, an electronic device that includes the eye-safe light source, and a method for manufacturing the eye-safe light source.

### BACKGROUND ART

In recent years, optical wireless communication modules represented by Infrared Data Association (IrDA) and the like, optical sensor modules, and the like have been widely mounted on electronic devices such as a mobile phone and a laptop computer. For example, PTL 1 discloses an optical proximity sensor (reflection type optical coupling device) that is mounted on a mobile phone.

Safety of eyes of a person (eye safe) should be secured for a light source that is used for optical wireless communication, optical sensing, and the like. In addition, since such a light source is used for optical wireless communication, optical sensing, and the like, light distribution characteristics need to be adjusted.

PTL 2 discloses a “light source device that may secure the safety of eyes of a person even in a case where a high power semiconductor laser is used as a light source element”. For example, the following configurations are disclosed. One configuration is such that, as illustrated in part (a) of FIG. 16, a semiconductor laser 1100 is arranged in a recess part 1110, the recess part 1110 is filled with a resin 1120 in which a light scatterer is uniformly distributed at high density, and the resin 1120 is cured. Such a configuration converts highly coherent light into harmless incoherent light that does not damage eyeballs of a person, while a laser light ray passes through the resin 1120 in which the light scatterer is uniformly distributed at high density. Another configuration is such that, as illustrated in part (b) of FIG. 16, an electrolyte solution 1210 that includes a light scatterer is separated from a semiconductor laser 1200 so that the electrolyte solution 1210 is not in direct contact with the semiconductor laser 1200, and laser light passes through the solution 1210 including the light scatterer. Another configuration is such that, as illustrated in (c) of FIG. 16, a wire 1330 that is connected to a semiconductor laser 1300 passes through a mold part 1310 and a resin 1320 in order to secure eye safety even in a case where the mold part 1310 or the resin 1320 that includes a light scatterer is broken.

### CITATION LIST

### Patent Literature

PTL 1: Japanese Unexamined Patent Application Publication No. 2011-96724 (published on May 12, 2011)

PTL 2: Japanese Patent No. 4014425 (issued on Nov. 28, 2007)

### SUMMARY OF INVENTION

### Technical Problem

Generally, a scattering resin that is configured by mixing a light scatterer in a liquid state resin (base material) tends to have higher viscosity than the base material and also higher hardness after curing. This tendency is more noticeable as the concentration at which the light scatterer is mixed increases. Since the scattering resin in which the light scatterer is mixed at a high concentration is hard, a crack occurs easily.

Thus, in the configuration in part (a) of FIG. 16 in which the semiconductor laser 1100 is directly sealed with the resin 1120 in which the light scatterer is mixed at a high concentration, problems arise in that (i) since the semiconductor laser 1100 receives high stress from the sealing resin 1120, and defects increase in the semiconductor laser 1100, the semiconductor laser 1100 experiences a sudden turn-off, (ii) since a crank occurs in the sealing resin 1120, and a wire that is connected to the semiconductor laser 1100 is broken due to the crack, electric power may not be supplied to the semiconductor laser 1100, and (iii) since laser light is concentrated in a minute region of a few μm² to a few tens of μm² in the vicinity of the light emission end surface of the semiconductor laser 1100, slight absorption of the laser light by the light scatterer contained in the sealing resin 1120 locally increases temperature, and the light emission end surface of the semiconductor laser 1100 at a high temperature may cause catastrophic optical damage (COD).

That is, such a configuration as the configuration described in part (a) of FIG. 16 has a problem that the lifetime of a light source device is short.

In addition, in the configuration in part (b) of FIG. 16 in which the semiconductor laser 1200 is air-sealed by covering the opening of a tube part 1230 accommodating the semiconductor laser 1200 with a transparent glass 1220, only the peripheral part of the transparent glass 1220 is fixed to the tube part 1230. Thus, the fixed area of the transparent glass 1220 is small, and a problem arises in that the transparent glass 1120 is easily separated from the tube part 1230 by temporal degradation or external force.

The present invention is conceived in view of such a problem. An object of the present invention is to implement an eye-safe light source that has a long lifetime and includes a lid which is not easily separated from a container.

### Solution to Problem

In order to address the above object, an eye-safe light source according to an embodiment of the present invention is configured to include a semiconductor laser that emits laser light; a container that includes a bottom surface on which the semiconductor laser is mounted, a reflective surface on which the laser light is reflected, and an opening through which the reflected laser light is radiated; a lid that covers at least part of the opening; and a sealing resin that is disposed in the container, seals the semiconductor laser, and fixes the lid to the container.

In order to address the above object, a method for manufacturing an eye-safe light source according to an embodiment of the present invention is a method including a semiconductor laser mounting step of mounting a semiconductor laser that emits laser light on a bottom surface of a container that includes a reflective surface on which the laser light is reflected, and an opening through which the reflected laser light is radiated; a lid mounting step of mounting a lid including a first hole on the container such that the lid covers at least part of the opening; a filling step of filling the container with a first resin through the first hole until at least the first resin comes into contact with the lid; and a curing step of curing the first resin after filling, in which the cured first resin fixes the lid to the container.

In order to address the above object, another method for manufacturing an eye-safe light source according to an embodiment of the present invention is a method including a semiconductor laser mounting step of mounting a semiconductor laser that emits laser light on a bottom surface of a container that includes a reflective surface on which the laser light is reflected, and an opening through which the reflected laser light is radiated; a filling step of filling the container with a first resin; a lid mounting step of mounting a lid such that the lid comes into contact with the first resin, and the lid covers at least part of the opening; and a curing step of curing the first resin in contact with the lid, in which the cured first resin fixes the lid to the container.

In order to address the above object, still another method for manufacturing an eye-safe light source according to an embodiment of the present invention is a method including a semiconductor laser mounting step of mounting a semiconductor laser that emits laser light on a bottom surface of a container that includes a reflective surface on which the laser light is reflected, and an opening through which the reflected laser light is radiated; a filling step of filling the container with a first resin; a temporary curing step of temporarily curing the first resin after filling; a refilling step of further filling the container with a second resin on the temporarily cured first resin; and a main curing step of curing the temporarily cured first resin and the second resin after filling at the same time, in which the cured second resin is a lid that covers at least part of the opening, and the cured first resin fixes the lid to the container.

### Advantageous Effects of Invention

According to the present invention, the lid is fixed to the container through the sealing resin in the container or the cured first resin. Thus, at least part of a region of the surface of the lid that faces the opening contributes to the fixing of the lid to the container. Accordingly, an effect that the lid is not easily separated from the container, and a loss of eye safety caused by the separation of the lid from the eye-safe light source is prevented is achieved.

### BRIEF DESCRIPTION OF DRAWINGS

FIG. 1 is a sectional view illustrating a schematic configuration of an eye-safe light source according to Embodiment 1 of the present invention.

FIG. 2 is a view illustrating the eye-safe light source illustrated in FIG. 1 without a transparent resin layer and a cover.

FIG. 3 is a view illustrating a schematic configuration of the cover included in the eye-safe light source illustrated in FIG. 1.

FIG. 4 is a view for describing a method for manufacturing the eye-safe light source illustrated in FIG. 1 in order.

FIG. 5 is a view for describing another method for manufacturing the eye-safe light source illustrated in FIG. 1 in order.

FIG. 6 is a view illustrating a schematic configuration of a cover that is a modification example of the cover illustrated in FIG. 3.

FIG. 7 is a view illustrating a schematic configuration of a cover that is a modification example of the cover illustrated in FIG. 3.

FIG. 8 is a view illustrating a schematic configuration of an eye-safe light source in which a package that is a modification example of a package illustrated in FIG. 2 is used.

FIG. 9 is a view illustrating a schematic configuration of an eye-safe light source according to Embodiment 2 of the present invention.

FIG. 10 is a view for describing a method for manufacturing an eye-safe light source according to Embodiment 3 of the present invention.

FIG. 11 is an enlarged view for describing a case where the filling amount of a liquid state transparent resin forming a transparent resin layer and the filling amount of a liquid state scattering resin forming a cover are (a) excessively large or (b) excessively small in the method for manufacturing the eye-safe light source illustrated in FIG. 10.

FIG. 12 is a sectional view for describing an eye-safe light source according to Embodiment 4 of the present invention.

FIG. 13 is a sectional view illustrating a schematic configuration of an eye-safe light source according to Embodiment 5 of the present invention.

FIG. 14 is a sectional view illustrating a schematic configuration of an eye-safe light source according to Embodiment 6 of the present invention.

FIG. 15 is a view illustrating a schematic configuration of an optical sensor according to Embodiment 7 of the present invention.

FIG. 16 is a view illustrating a related art described in PTL 2.

### DESCRIPTION OF EMBODIMENTS

### Embodiment 1

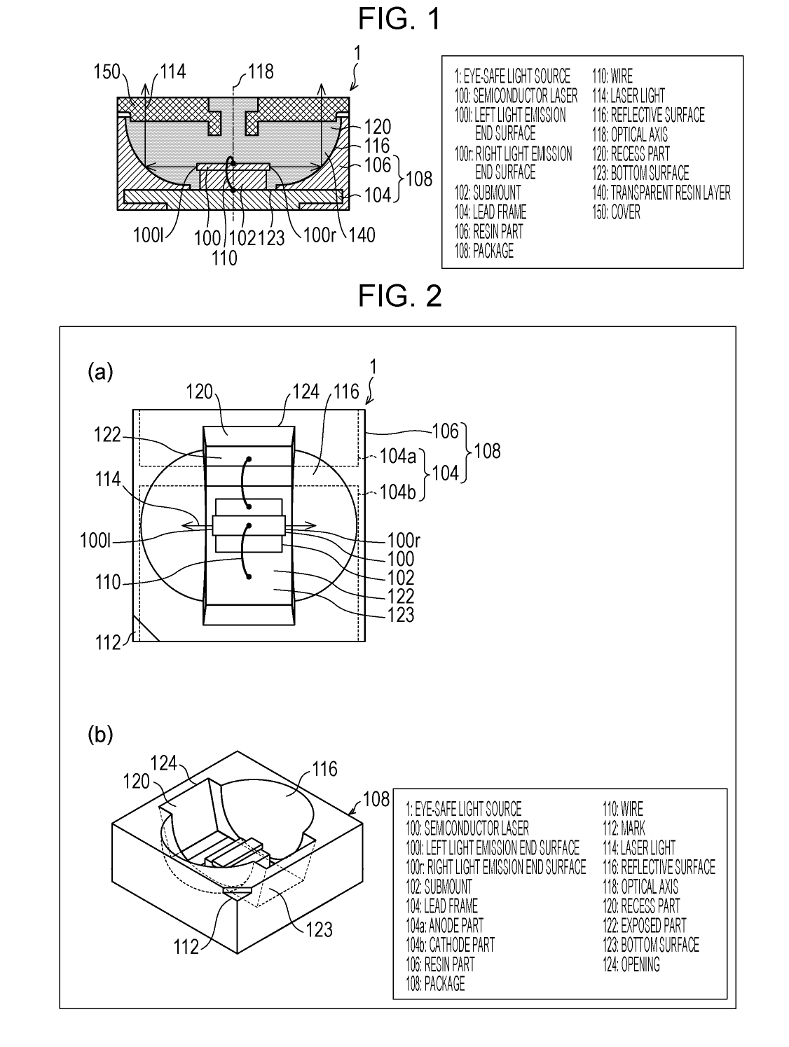

Hereinafter, Embodiment 1 of the present invention will be described in detail based on FIG. 1 to FIG. 7.

FIG. 1 is a sectional view illustrating a schematic configuration of an eye-safe light source 1 according to Embodiment 1 of the present invention. While a direction in which the eye-safe light source 1 radiates light from an opening 124 of a recess part 120 is an upward direction in the following description, the direction of the eye-safe light source 1 at the time of manufacturing, use, and the like is not limited thereto.

As illustrated in FIG. 1, the eye-safe light source 1 includes a semiconductor laser 100, a submount 102, a package 108 (container), wires 110, a transparent resin layer 140 (a sealing resin or a cured first resin), and a cover 150 (lid). The semiconductor laser 100 emits laser light 114 from a left light emission end surface 1001 and a right light emission end surface 100r. The semiconductor laser 100 is mounted on the submount 102. The recess part 120 is formed in the package 108. The wires 110 are connected to the semiconductor laser 100. The transparent resin layer 140 is configured by curing a liquid state resin with which the recess part 120 is filled. The cover 150 covers the opening 124 of the recess part 120. The eye-safe light source 1 is a surface-mount type.

An optical axis 118 indicates a direction in which light that is made eye-safe is emitted from the eye-safe light source 1. The optical axis 118 is perpendicular to the upper surface of a lead frame 104 and the upper surface of the package 108.

(Package)

Hereinafter, the package 108 will be described based on FIG. 2.

FIG. 2 is a view illustrating the eye-safe light source 1 illustrated in FIG. 1 without the transparent resin layer 140 and the cover 150. Therefore, FIG. 2 illustrates a schematic configuration of the package 108 included in the eye-safe light source 1 illustrated in FIG. 1, and a schematic arrangement of the semiconductor laser 100 with respect to the package 108. Part (a) of FIG. 2 is a top view illustrating the lead frame 104 that is seen through a resin part 106, and part (b) of FIG. 2 is a perspective view illustrating the recess part 120 that is seen through the resin part 106.

The package 108 is a member in which the surrounding area of the lead frame 104 is partially covered (packaged) with the resin part 106. The semiconductor laser 100 is accommodated in the recess part 120 that is formed in the package 108. A mark 112 is disposed in the package 108 so that the directions of an anode and a cathode are recognized.

The recess part 120 has a bottom surface 123, a reflective surface 116, and the opening 124. A part (exposed part 122) of the upper surface of the lead frame 104 is exposed from the bottom surface 123. The semiconductor laser 100 is mounted on the exposed part 122 of the exposed lead frame 104 through the submount 102. The reflective surface 116 reflects the laser light 114. The semiconductor laser 100 is mounted on the bottom surface 123 such that both left and right light emission end surfaces 100r and 1001 face the reflective surface 116. The opening 124 is open on the upper surface of the package 108. The laser light 114 that is reflected by the reflective surface 116 is radiated to the outside of the eye-safe light source 1 from the opening 124.

The lead frame 104 is configured by stamping a thin plate of metal such as a copper-based alloy, and plating the stamped plate. The lead frame 104 has excellent thermal conductivity, thermal radiation properties, mechanical strength, and electrical conductivity. On the upper surface of the lead frame 104, the exposed part 122 is exposed toward the recess part 120 from the bottom surface 123 without being covered with the resin part 106 in order to be electrically and thermally connected to the semiconductor laser 100. Most part of the lower surface of the lead frame 104 is exposed downward from the resin part 106 in order to radiate heat. The lead frame 104 is electrically connected to the outside through a lead terminal that is not illustrated in FIG. 1. Alternatively, the lead frame 104 may be electrically connected to the outside through the lower surface of the lead frame 104 that is exposed from the resin part 106.

The lead frame 104 includes a cathode part 104b and an anode part 104a. The cathode part 104b is connected to the cathode of the semiconductor laser 100. The anode part 104a is connected to the anode of the semiconductor laser 100.

The cathode part 104b and the anode part 104a are joined to each other by the resin part 106, and are insulated from each other by the resin part 106. The submount 102 on which the semiconductor laser 100 is mounted is joined onto the exposed part 122 of the cathode part 104b. The cathode part 104b and the anode part 104a may be opposite to each other in size and arrangement with respect to the semiconductor laser 100.

A resin that forms the resin part 106 is a white thermoplastic resin containing a light scatterer that scatters the laser light 114, and is a resin that is generally used in a light emitting diode (LED) light source.

The resin part 106 may be formed of, for example, a polycyclohexylenedimethylene terephthalate (PCT) resin or polyphthalamide (PPA) resin. While a white resin is used in order to improve reflectance, a resin of other colors such as red may be used depending on the wavelength of the laser light 114 and the application of the eye-safe light source 1. In addition, while a thermoplastic resin is used, a resin having other properties such as a thermosetting resin and a photo-curable resin may be used depending on a method for manufacturing the package 108.

Infrared light has the lowest energy per photon among infrared light, visible light, and ultraviolet light. Thus, in a case where the resin part 106 is formed of a resin (a PCT resin, a PPA resin, or the like) that is generally used for packaging a blue LED and a white LED with a resin, the resin part 106 has sufficient durability and long-term reliability with respect to the laser light 114 emitted from the semiconductor laser 100 in a case where an infrared laser is used as the semiconductor laser 100. The semiconductor laser 100 is not limited thereto. A visible light semiconductor laser (for example, a blue semiconductor laser, a green semiconductor laser, or a red semiconductor laser) that emits laser light of a wavelength in the visible light range may be used as the semiconductor laser 100.

While illustration is not provided in FIG. 1 and FIG. 2, a control element for controlling the light emission of the semiconductor laser 100 may be joined to the lead frame 104 and resin-sealed by the resin part 106. It should be noted that other semiconductor elements may be resin-sealed inside the package 108.

The mark 112 is formed as a recess having an isosceles right triangle shape in the resin part 106 on the upper surface of the package 108. Accordingly, since the mark 112 may be formed at the same time as the formation of the resin part 106, errors in the position of the mark 112 may be prevented. The mark 112 may not be disposed.

(Shape of Recess Part)

In the present embodiment, the shape of the recess part 120 is a three-dimensional shape configured by superimposing an approximately reversed quadrangular truncated pyramid with an approximately paraboloidal body of revolution such that the upper bottom of the approximately reversed quadrangular truncated pyramid are in the same plane as the bottom surface of the approximately paraboloidal body of revolution. The reflective surface 116 that reflects the laser light 114 is a curved surface part of the approximately paraboloidal body of revolution. The exposed part 122 on the upper surface of the lead frame 104 is exposed from the lower bottom part of the approximately reversed quadrangular truncated pyramid. The shape of the recess part 120 is not limited thereto. The reflective surface 116 may be another curved surface such as the side surface of a tube or a spherical surface. The recess part 120 may have a simple shape such as an approximately reversed quadrangular truncated pyramid or an approximately reversed circular truncated cone.

(Submount and Semiconductor Laser)

As illustrated in part (a) of FIG. 2, the submount 102 is joined to the center of the bottom surface 123 of the recess part 120 of the package 108, and is joined to the exposed part 122 of the cathode part 104b of the lead frame 104. The submount 102 is electrically connected to the anode of the semiconductor laser 100, and is electrically connected to the anode part 104a of the lead frame 104 through the wires 110. In addition, the submount 102 is thermally connected to the semiconductor laser 100, and is thermally connected to the cathode part 104b of the lead frame 104.

The semiconductor laser 100 is an infrared semiconductor laser that emits laser light of a wavelength longer than 700 nm. In addition, as illustrated in part (a) of FIG. 2, the semiconductor laser 100 symmetrically emits the laser light 114 from both light emission end surfaces configured with the left light emission end surface 1001 and the right light emission end surface 100r. Therefore, the left and right light emission end surfaces 1001 and 100r of a resonator formed in the semiconductor laser 100, and the vicinity of the left and right light emission end surfaces 1001 and 100r are optically symmetric. For example, the equivalent optical end surface coating may be performed on the left light emission end surface 1001 and the right light emission end surface 100r of the semiconductor laser 100, or the equivalent optical window structure may be formed in the left light emission end surface 1001 and the right light emission end surface 100r of the semiconductor laser 100. Alternatively, the left light emission end surface 1001 and the right light emission end surface 100r of the semiconductor laser 100 may be exposed without either the optical end surface coating or the optical window structure.

(Wire)

The wires 110 are gold wires and are electric power lines through which electric power for driving the semiconductor laser 100 is supplied. Thus, a breakage in the wires 110 stops driving of the semiconductor laser 100.

One wire 110 connects the cathode of the semiconductor laser 100 to the cathode part 104b of the lead frame 104. This wire 110 extends forward (downward in part (a) of FIG. 2) from the semiconductor laser 100. When the wire 110 is seen from the direction of the optical axis 118, the wire 110 is approximately orthogonal to the optical axis of the laser light 114 that is emitted parallel to the upper surface of the lead frame 104.

Another wire 110 connects the anode part 104a of the lead frame 104 to the submount 102 that is connected to the anode of the semiconductor laser 100. The other wire 110 extends backward (upward in part (a) of FIG. 2) from the submount 102. When the other wire 110 is seen from the direction of the optical axis 118, the other wire 110 is approximately orthogonal to the optical axis of the laser light 114 that is emitted parallel to the upper surface of the lead frame 104.

The two wires 110 pass through the transparent resin layer 140. Thus, when the transparent resin layer 140 is separated from the package 108, both wires 110 or any one of the two wires 110 is broken. Furthermore, both wires 110 are completely sealed in the transparent resin layer 140.

Thus, since both wires 110 does not pass through a boundary surface between different substances that are strongly affected by thermal expansion and thermal contraction, a breakage in both wires 110 caused by a change in temperature is suppressed when the transparent resin layer 140 is fixed to the package 108.

(Reflective Surface)

Hereinafter, the reflective surface 116 that reflects the laser light 114 will be described.

The reflective surface 116 includes a pair of side surfaces that face each other among the side surfaces of the recess part 120. The reflective surface 116 faces the left light emission end surface 1001 and the right light emission end surface 100r of the semiconductor laser 100 that emits the laser light 114. The reflective surface 116 has plane symmetry about a plane (first plane of symmetry) that passes through the center (a middle point between the left light emission end surface 1001 and the right light emission end surface 100r) of the semiconductor laser 100 and is perpendicular to the direction in which the semiconductor laser 100 emits the laser light 114. In addition, the reflective surface 116 has plane symmetry about a plane (second plane of symmetry) that passes through the light emission center of the left light emission end surface 1001 and the light emission center of the right light emission end surface and is perpendicular to the upper surface of the lead frame 104 and parallel to the direction in which the semiconductor laser 100 emits the laser light 114.

The reflective surface 116 is a curved surface that is inclined upward with respect to the upper surface of the lead frame 104 such that the curved surface is open upward. By this inclination, the laser light 114 that is emitted parallel to the upper surface of the lead frame 104 is reflected in the direction of the optical axis 118. In addition, since the reflective surface 116 is the surface of the resin part 106 that contains the light scatterer, the reflective surface 116 diffusely reflects the laser light 114. This scatter reflection increases the spot diameter of the laser light 114. Thus, after reflection, the light density of the laser light 114 is decreased from that before reflection.

The reflective surface 116 may be configured by performing metal plating on the surface of the resin part 106. Due to the metal plating, the reflective surface 116 becomes a metal surface that reflects the laser light 114 without scattering. Metal plating may be performed or may not be performed on the side surfaces of the recess part 120 other than the reflective surface 116. In a case where the semiconductor laser 100 emits laser light of a relatively short wavelength, for example, in a case where the semiconductor laser 100 is a blue semiconductor laser that emits blue laser light, or an ultraviolet semiconductor laser that emits laser light of a wavelength in the ultraviolet range, the reflective surface 116 is preferably a metal surface. Light in the blue range, the blue violet range, and the ultraviolet range has a high energy per unit photon, and the deterioration of the resin is likely to proceed by irradiation. Thus, in a case where the reflective surface 116 is a resin surface, the reflectance of the reflective surface 116 is significantly decreased. Meanwhile, in a case where a metal having a high reflectance is irradiated with such light, heat is favorably radiated with a small energy loss, and deterioration such as that of the resin is not seen. Thus, in a case where the reflective surface 116 is a metal surface, a significant decrease in the reflectance of the reflective surface 116 does not occur.

(Cover)

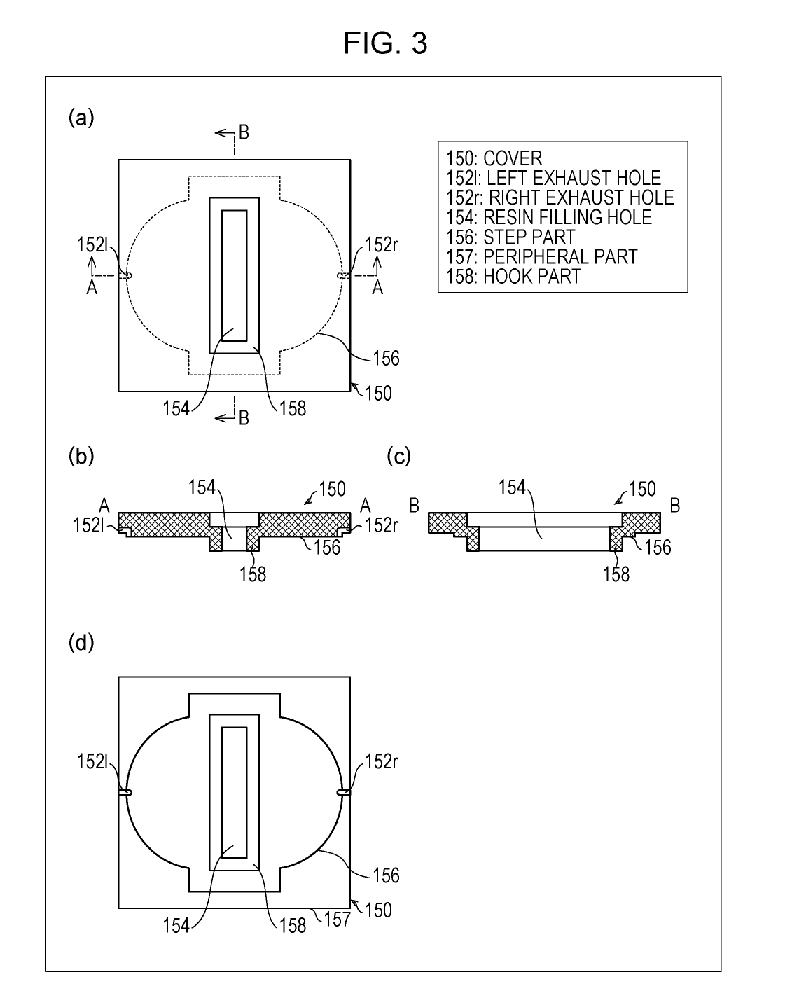

Hereinafter, the cover 150 will be described based on FIG. 3.

FIG. 3 is a view illustrating a schematic configuration of the cover 150 included in the eye-safe light source 1 illustrated in FIG. 1. Part (a) of FIG. 3 illustrates a top view. Part (b) of FIG. 3 illustrates an AA sectional view of part (a) of FIG. 3. Part (c) of FIG. 3 illustrates a BB sectional view of part (a) of FIG. 3. Part (d) of FIG. 3 illustrates a bottom view.

As illustrated in FIG. 3, the cover 150 includes a left exhaust hole 1521 (second hole) and a right exhaust hole 152r (second hole) for discharging air (alternatively, inert gas or the like), a resin filling hole 154 (first hole) for filling of a liquid state resin forming the transparent resin layer 140, a step part 156 (fitting part) for fitting in the opening 124 of the recess part 120, and a hook part 158 (interlocking part) for interlocking with the transparent resin layer 140.

The cover 150 is an optical cover that is formed in advance from a scattering resin configured by mixing, in a transparent resin (base material) through which the laser light 114 passes, a filler (light scatterer) which scatters the laser light 114. Thus, by the scattering, the spot diameter of the laser light 114 that passes through the cover 150 increases. The light density inside the spot averages out, and the laser light 114 is made eye-safe.

The resin that forms the cover 150 contains the light scatterer at a higher density (second content weight percent) than the resin forming the transparent resin layer 140 such that the laser light 114 is mainly scattered by the cover 150. In order for the laser light 114 passing through the cover 150 to be able to be transmitted through appropriate scattering, the wt % concentration (second content weight percent) of the light scatterer with respect to the base material in the resin forming the cover 150 is preferably greater than or equal to 0.02% and less than or equal to 10%, more preferably greater than or equal to 0.05% and less than or equal to 5%, and further preferably greater than or equal to 0.1% and less than or equal to 0.2% in a case where, for example, a titanium oxide that is a representative light scatterer is added to a dimethyl silicone that is a representative silicone-based resin as the base material of the transparent resin.

The upper limit of the concentration of the titanium oxide as the light scatterer with respect to the dimethyl silicone as the base material is determined by whether or not a liquid state substance that is acquired in the case of mixing and agitating both the titanium oxide and the dimethyl silicone has fluidity. In a case where the wt % concentration of the titanium oxide is greater than or equal to 10%, viscosity increases, and the fluidity of the mixed resin is significantly decreased. Thus, such a case is not appropriate for manufacturing the cover 150. In addition, the cover that is acquired from a mixture in a high concentration region loses flexibility that the silicone resin originally has. In a case where the cover is exposed to a high temperature or a low temperature, the cover becomes fragile, and a crack easily occurs in the cover. Thus, considering the easiness of manufacturing of the cover 150 and the level of reliability such that a crack does not easily occur, the wt % concentration of the titanium oxide with respect to the dimethyl silicone is desirably less than or equal to 5% and, if possible, less than or equal to 2%.

Meanwhile, such restrictions based on a decrease in the fluidity of the resin and a decrease in reliability may not be considered for the lower limit of the concentration of the titanium oxide that is a mixable light scatterer. The amount of the titanium oxide to be added is determined by considering necessary light distribution control. However, in a case where the wt % concentration of the titanium oxide with respect to the dimethyl silicone is below 0.02%, even a small amount of titanium oxide needs to be mixed and agitated in a sufficient amount of resin in order to control the weight percent with high accuracy. Thus, such a case is not economical in terms of the efficiency of material use. Furthermore, in the case of desiring to achieve a sufficient effect of securing eye safety in a region where the concentration of the titanium oxide that is a light scatterer is low, the thickness of the cover 150 is greater than the thickness of the main body of the package 108, and such a case is not practical for the purpose of a small light source that needs to have a small size and a small thickness. From such a viewpoint, the lower limit of the wt % concentration is naturally restricted, and it is preferable to mix the titanium oxide in the dimethyl silicone at a wt % concentration of greater than or equal to 0.05, and more preferably greater than or equal to 0.1%.

For example, the wt % concentration of the titanium oxide with respect to the dimethyl silicone may be approximately greater than or equal to 0.1% and less than or equal to 2% in the case of manufacturing the cover 150 having a thickness of 1.0 mm by mixing the titanium oxide in the dimethyl silicone, and may be greater than or equal to 0.2% and less than or equal to 5% in the case of manufacturing the cover 150 having a thickness of 0.5 mm.

Strictly speaking, the concentration of such a light scatterer depends on the viscosity and the specific weight (density) of the base material and the specific weight (density) and the particle diameter of the light scatterer. However, the above values provide a good indication. For example, in the case of silica that is generally used as the light scatterer like the titanium oxide, the specific weight of the silica is only 1.8 to 2.2 g/cm³ which is the half of the specific weight of the titanium oxide of 4.2 g/cm³. Considering this point, a practical wt % concentration of the silica with respect to the dimethyl silicone is 0.01% to 5%. Similarly, alumina (Al₂O₃) or zirconia (ZrO₂) that is known as a representative light scatterer may be considered in the similar manner.

The particle diameter of the filler used as the light scatterer is in a wide range of a significantly small few nm to a few tens of μm. In a case where the filler having a small particle diameter is mixed, viscosity generally tends to increase, compared to a filler having the same weight and a larger particle diameter. In the case of a porous particle, viscosity further increases. Thus, while the example described with the titanium oxide may not be uniformly applied, the example is effective as an indication. The same applies to a case where the resin as the base material is another resin such as an epoxy-based resin.

The left and right exhaust holes 1521 and 152r are disposed on both left and right sides of the resin filling hole 154 such that a bubble (void) does not remain in the recess part 120 (in the transparent resin layer 140, and between the transparent resin layer 140 and the cover 150). The left and right exhaust holes 1521 and 152r extend to the side surface or the upper surface of the cover 150 from the lower surface of the cover 150. In addition, the left and right exhaust holes 1521 and 152r are formed outside the optical path of the laser light 114 in order not to affect the light distribution characteristics of the eye-safe light source 1.

The resin filling hole 154 is disposed at the center of the cover 150 such that the resin filling hole 154 passes from the upper surface to the lower surface of the cover 150 in order to fill the recess part 120, of which the opening 124 is covered with the cover 150, with a liquid state resin. The resin filling hole 154 is formed outside the optical path of the laser light 114 in order not to affect the light distribution characteristics of the eye-safe light source 1.

The step part 156 is formed in a shape that complements the opening 124, so as to fit in the opening 124 of the recess part 120. The step part 156 is disposed as a protrusion on the lower surface of the cover 150. When the cover 150 is mounted on the package 108, the step part 156 fits in the opening 124 of the recess part 120, and a peripheral part 157 outside the step part 156 comes into contact with the upper surface of the package 108. By fitting of the step part 156 in the opening 124, the cover 150 may be mounted at an appropriate position on the upper surface of the package 108 without deviating from the recess part 120. In addition, a positional deviation of the cover 150 from the opening 124 in the middle of manufacturing is prevented.

The hook part 158 is formed in a shape that interlocks with the transparent resin layer 140 in order to reinforce the engagement between the transparent resin layer 140 and the cover 150. In addition, the hook part 158 is preferably disposed in the resin filling hole 154 (or in the vicinity thereof) so that a void does not occur around the hook part 158. The hook part 158 may have a shape that does not interlock but only increases a fixing area in which the transparent resin layer 140 and the cover 150 are in contact with each other. The reason is that increasing the fixing area that contributes to fixing of the cover 150 reinforces the fixing between the transparent resin layer 140 and the cover 150. In addition, the hook part 158 is formed outside the optical path of the laser light 114 in order not to affect the light distribution characteristics of the eye-safe light source 1.

The shape of the cover 150, the arrangement and the number of exhaust holes for discharging air and resin filling holes for filling of the resin forming the transparent resin layer 140, and the shape and the arrangement of the hook part 158 are not limited to those above. The cover 150 may be able to cover at least a position (optical path) at which the laser light 114 passes through in the opening 124 so that the filling of the resin forming the transparent resin layer 140 or the mounting of the cover 150 may be performed without generating the void, and the laser light 114 may be made eye-safe.

(Transparent Resin Layer)

Hereinafter, the transparent resin layer 140 will be described based on FIG. 1.

The transparent resin layer 140 is a resin layer that is formed of only a transparent resin (base material) through which the laser light 114 is transmitted, or a resin configured by slightly mixing, in the base material, the light scatterer that scatters the laser light 114. The resin forming the transparent resin layer 140 has a higher transmittance at which the laser light 114 is transmitted, than the resin forming the cover 150. In a case where the light scatterer is mixed in the resin forming the transparent resin layer 140, the concentration of the contained light scatterer is within a range that does not affect the flexibility of the transparent resin layer 140 after curing, and within a range that does not cause a local increase in temperature in the vicinity of the left and right light emission end surfaces 1001 and 100r of the semiconductor laser 100. Therefore, in the resin forming the transparent resin layer 140, the wt % concentration (first content weight percent) of the light scatterer with respect to the base material is preferably less than or equal to 2%, more preferably less than or equal to 0.1%, and further preferably less than or equal to 0.02%. Thus, the transparent resin layer 140 does not or almost not contain the light scatterer and is flexible.

As in the description of the cover 150, the transparent resin layer 140 will be illustratively described in the case of the titanium oxide as the light scatterer and the dimethyl silicone that is a representative silicone-based resin as the base material of the transparent resin.

In a case where the titanium oxide having a wt % concentration of greater than or equal to 5% is mixed in the dimethyl silicone, the hardness of the mixed resin after curing increases. Thus, the semiconductor laser 100 that is directly covered with such a mixed resin receives stress from the resin, and defects increase in crystals. The semiconductor laser 100 experiences a sudden turn-off. In addition, the wires 110 are broken, and the lifetime of the semiconductor laser is decreased. Thus, the wt % concentration is desirably less than or equal to 5%.

Furthermore, in the vicinity of the light emission end surfaces 1001 and 100r of the semiconductor laser 100, the laser light is concentrated in a minute region of a few μm² to a few tens of μm². Thus, slight absorption of the laser light by the light scatterer contained in the sealing resin layer locally increases temperature, and the light emission end surface of the semiconductor laser 100 has a high temperature. Therefore, in order to avoid a problem that catastrophic optical damage (COD) easily occur, the wt % concentration of the titanium oxide with respect to the dimethyl silicone is required to be less than or equal to at least 2% and more preferably less than or equal to 0.1%. Furthermore, in a case where the wt % concentration is less than or equal to 0.02%, such adverse effects may be almost ignored.

As in the description of the cover 150, strictly speaking, the concentration of the light scatterer depends on the viscosity or the specific weight (density) of the base material and the specific weight (density) or the particle diameter of the light scatterer. Thus, the similar consideration is established for the light scatterer that is mixed in the transparent resin layer. Therefore, in the case of not only the cover 150 but also the sealing resin layer, the value of the wt % concentration related to the case of mixing the titanium oxide in the dimethyl silicone provides a good indication for other materials. That is, while the example described with the titanium oxide and the silicone-based resin may not be uniformly or totally applied for all resins and all light scattering bodies, the example provides an indication for various combinations of other substances, for example, a light scatterer such as the titanium oxide, silica, alumina, or zirconia and a base material such as a silicon-based resin including not only the epoxy-based resin and the dimethyl silicone but also methyl phenyl silicone.

The transparent resin layer 140 resin-seals the semiconductor laser 100 and the wires 110.

The transparent resin layer 140 is fixed to the cover 150 more tightly than to the package 108. Specifically, the transparent resin layer 140 is fixed in contact with at least part of a region (a region on the inner side of the step part 156) of the lower surface of the cover 150 on the inner side of the peripheral part 157 that comes into contact with the package 108. The transparent resin layer 140 is preferably fixed in contact with the whole region on the inner side of the step part 156. Furthermore, the transparent resin layer 140 interlocks with the hook part 158 of the cover 150 and preferably fills the left and right exhaust holes 1521 and 152r and the resin filling hole 154. Accordingly, the transparent resin layer 140 strongly engages with the cover 150 as a single body by a wide fixing area and an interlocking structure.

The resin forming the transparent resin layer 140 preferably has a high affinity with the resin forming the cover 150 in order to provide strong fixing between the transparent resin layer 140 and the cover 150. Therefore, the base material of the resin forming the transparent resin layer 140 is preferably the same kind of resin as the base material of the resin forming the cover 150.

(Lifetime)

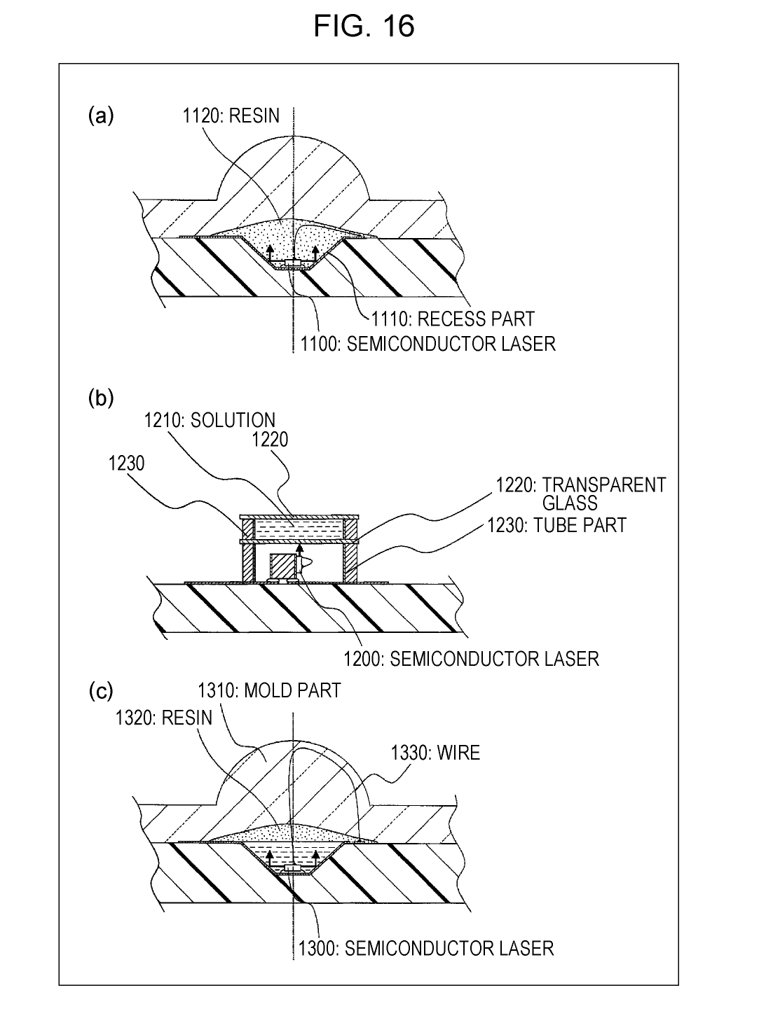

In the related art, in a configuration in which a semiconductor laser 1100 is directly sealed with a resin 1120 in which a light scatterer is mixed at a high concentration as in part (a) of FIG. 16, the semiconductor laser 1100 experiences frequent sudden turn-offs in a few tens of hours to a few hundreds of hours in a case where the semiconductor laser 1100 is continuously driven. A problem arises in that the lifetime of a light source device is short.

Meanwhile, in the eye-safe light source 1 according to the present embodiment, (i) since the transparent resin layer 140 is flexible, external force that is exerted on the semiconductor laser 100 may be buffered, (ii) since the transparent resin layer 140 is flexible, a crack does not easily occur under a rough condition such as a high temperature operation, and (iii) since the transparent resin layer 140 does not or almost not contain the light scatterer, a local increase in temperature in the vicinity of the light emission end surfaces 100r and 1001 of the semiconductor laser 100 is not caused. Therefore, compared to the configuration in part (a) of FIG. 16, the eye-safe light source 1 according to the present embodiment may increase the lifetime of the light source device.

A configuration such as part (b) of FIG. 16 may also increase the lifetime of the light source device since a solution 1210 that contains the light scatterer is separated from a semiconductor laser 1200. However, according to PTL 2, the solution 1210 that contains the light scatterer is separated from the semiconductor laser 1200 only for the reason that the solution 1210 is an electrolyte. The effect of the light scatterer on the semiconductor laser 1200 is not disclosed.

Furthermore, considering a historical background related to the semiconductor laser, the configuration such as part (b) of FIG. 16 assumes that the semiconductor laser is air-sealed. In early stages of developing the semiconductor laser, a resin that may endure light of a high density such as laser light, or a resin that is appropriate for protecting the semiconductor laser is not present. Thus, the semiconductor laser is air-sealed with air or inert gas in a metal container (tube part 1230) in which a glass window (transparent glass 1220) is disposed. Air sealing in the metal container has excellent stability and airtightness.

Thus, the semiconductor laser does not need to be resin-sealed. Thus, along with advances in illumination technology using a blue LED, a flexible resin that has excellent light fastness, thermal resistance, and weatherproofness and is appropriate for resin sealing which does not easily exert a mechanical load caused by stress on a light emitting element is developed. However, the configuration in which the semiconductor laser is resin-sealed as in part (a) of FIG. 16 and the present invention belongs to a different technical genealogy from the configuration in which the semiconductor laser is air-sealed as in part (b) of FIG. 16.

(Non-Separability of Cover)

In a case where the size of the light source device is large, a screw may be used, or a claw may be disposed in the cover, and a socket that receives the claw may be disposed in the package, as a method for fixing the cover that covers the recess part of the package accommodating the semiconductor laser. In a case where the size of the light source device is small, it is not easily to use a screw, a claw, or the like, and the cover is generally fixed to the package.

However, in a case where the size of the light source device is small, particularly, within 5 mm×5 mm in a top view, the fixing area in which the cover and the container are in contact with each other is small. Thus, a problem arises in that the cover is easily separated from the container.

For example, in the configuration in part (b) of FIG. 16, the semiconductor laser 1200 is air-sealed inside the tube part 1230 and the transparent glass 1220, and above the semiconductor laser 1200, the solution 1210 that contains the light scatterer is sealed inside the tube part 1230 and the transparent glass 1220. It is not easy to form this configuration in a small light source device, and the transparent glass 1220 is fixed to only the peripheral part of the tube part 1230. Thus, the fixing of the transparent glass 1220 is weak.

Meanwhile, in the eye-safe light source 1 according to the present embodiment, the fixing between the cover 150 and the transparent resin layer 140, and the fixing between the package 108 and the transparent resin layer 140 contribute to the fixing of the cover 150 to the package 108. More specifically, in addition to the peripheral part 157 of the lower surface of the cover 150 that comes into contact with the package 108, a region (a region on the inner side of the step part 156) that faces the opening 124 of the recess part 120 contributes to the fixing of the cover 150 to the package 108.

Therefore, since the surface area of the cover 150 that contributes to the fixing of the cover 150 to the package 108 increases as compared with that in the related art, the cover 150 is not easily separated from the package 108. In addition, the fixing of the cover 150 to the package 108 through the transparent resin layer 140 is advantageous for a small light source device, particularly, a small light source device within 5 mm×5 mm in a top view. In addition, since the fixing of the cover 150 is secure and easy, the productivity of the eye-safe light source 1 may increase.

(Securing Eye Safety)

In the related art, eye safety when the light source device is broken is secured by a configuration in part (c) of FIG. 16 in which a wire 1330 passes through a part (a mold part 1310 and a resin 1320 that contains a light scatterer) that causes a loss of eye safety in a case where the part is broken, so that the wire 1330 is broken at the time of breakage. However, for example, when a part through which the wire does not pass is broken or detached, the wire is not broken, and a problem arises in that the emission of laser light from the semiconductor laser continues.

In addition, the configuration in part (b) of FIG. 16 has a safety problem. Specifically, eye safety is lost when the sealing of the solution 1210 is damaged by external force or temporal degradation. Furthermore, the configuration in part (c) of FIG. 16 in which eye safety at the time of breakage is secured by disconnecting the wire 1330 is not effective for a leakage of the solution 1210 containing the light scatterer. Thus, in a case where the solution 1210 containing the light scatterer leaks, or in a case where a region in which the solution 1210 containing the light scatterer is sealed is separated from a region in which the semiconductor laser 1200 is sealed, laser light that is emitted from the semiconductor laser 1200 is radiated to the outside without being made eye-safe. In such a case, highly coherent laser light reaches eyeballs, and there is a risk of damaging the retina.

Therefore, the configurations in the related art may not secure eye safety for a breakage and detachment of a part through which the wire does not pass, or a part that is not effective even in a case where the wire passes therethrough. Thus, from the fail-safe safety philosophy, the configurations in the related art bear risks.

Meanwhile, in the eye-safe light source 1 according to the present embodiment, the wires 110 are broken when the cover 150 is separated from the package 108 regardless of the fact that the wires 110 do not pass through the cover 150. The reason is that the wires 110 pass through the transparent resin layer 140, and the transparent resin layer 140 engages with the cover 150 more tightly than with the package 108. Accordingly, when the cover 150 is separated from the package 108, the transparent resin layer 140 is separated from the package 108 along with the cover 150, and the wires 110 passing through the transparent resin layer 140 are broken at the same time.

Therefore, from the fail-safe safety philosophy, the eye-safe light source 1 according to the present embodiment is safe.

(Light Distribution Characteristics and Light Polarization Characteristics)

While the laser light 114 is diffusely reflected on the reflective surface 116, the laser light 114 is not scattered or is almost not scattered while being transmitted through the transparent resin layer 140. Thus, the intensity distribution of the light density of the laser light 114 that is diffusely reflected by the reflective surface 116 appropriately averages out by the diffusion, and the light distribution characteristics at the time of emission from the left and right light emission end surfaces 1001 and 100r are almost maintained. Thus, by lowering the peak of high intensity on the optical axis (center of the spot) of the laser light 114 using the reflective surface 116, the intensity of the light density averages out between the surrounding area and the center of the spot, and the light distribution characteristics may be regulated. In addition, the laser light 114 is sufficiently made eye-safe by being transmitted through the cover 150 that contains the light scatterer scattering the laser light 114. Thus, in the eye-safe light source 1, the light distribution characteristics of the laser light 114 may be regulated while the laser light 114 is made eye-safe, and the light polarization characteristics of the laser light 114 may be at least partially maintained.

Meanwhile, in the configuration such as part (a) or (c) of FIG. 16, the recess part in which the semiconductor laser is arranged is filled with the resin that contains the light scatterer, and the laser light loses the light distribution characteristics and the light polarization characteristics by multiple scattering.

In addition, the degree of scattering in the cover 150, the reflective surface 116, and the transparent resin layer 140 may be adjusted depending on desired light polarization characteristics. By doing so, the polarization ratio of the laser light 114 radiated from the eye-safe light source 1 may be adjusted within a range of approximately 2 to 100. The polarization ratio is the ratio of the intensity of light having a principal polarization plane of the light source to the intensity of light having a polarization plane other than the principal polarization plane of the light source. In addition, in the eye-safe light source 1, while the light distribution characteristics may be regulated using the shape of the reflective surface 116, a lens may be appropriately disposed. For example, it is desirable to install a lens when the eye-safe light source 1 is used by optically coupling the eye-safe light source 1 to an optical fiber. The lens may be an external lens or may be integrated with the cover 150.

Accordingly, since the light distribution characteristics and the light polarization characteristics may be adjusted, the eye-safe light source 1 is appropriate for an application that uses the light polarization characteristics. For example, the eye-safe light source 1 may be included in an electronic device for biometric authentication.

(Void)

In a case where a bubble (void) is present in the transparent resin layer 140, the lifetime and the light distribution characteristics of the eye-safe light source 1 are affected. Thus, it is preferable that the void is not present. In a case where the void is not present, the lifetime of the eye-safe light source 1 may increase, and the light distribution characteristics may be made uniform.

Particularly, it is preferable that the void is not present in the vicinity of a boundary surface between the transparent resin layer 140 and the cover 150. The reason is that in a case where the void is present in the vicinity of the boundary surface, the fixing area in which the transparent resin layer 140 and the cover 150 are in contact with each other is substantially reduced by the void. Therefore, the lower surface of the cover 150 preferably has a shape that increases the area of contact with the transparent resin layer 140 without leaving the void.

(Manufacturing Method)

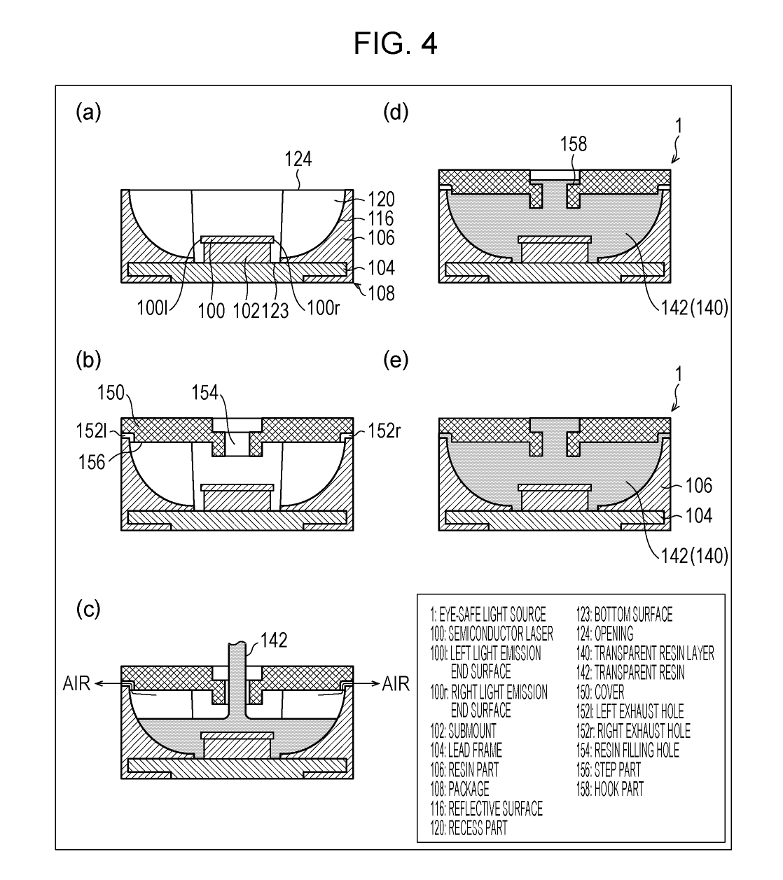

Hereinafter, a method (first manufacturing method) for manufacturing the eye-safe light source 1 will be described based on FIG. 4.

FIG. 4 is a view for describing the method for manufacturing the eye-safe light source 1 illustrated in FIG. 1 in order. In FIG. 4, the wires 110 is not illustrated.

As in part (a) of FIG. 4, the semiconductor laser 100 is mounted through the submount 102 on the bottom surface 123 of the recess part 120 on which the exposed part 122 of the lead frame 104 is exposed, such that both light emission end surfaces 1001 and 100r face the reflective surface 116 (semiconductor laser mounting step). One wire 110 is connected to the semiconductor laser 100 and the lead frame 104, and another wire 110 is connected to the submount 102 and the lead frame 104 (connecting step).

Next, an adhesive is applied on the peripheral part 157 of the lower surface of the cover 150, and the cover 150 is mounted on the upper surface of the package 108 such that the step part 156 of the cover 150 fits in the opening 124 of the recess part 120 as in part (b) of FIG. 4 (lid mounting step). The cover 150 is temporarily fixed to the package 108 by the adhesive.

Next, as in part (c) of FIG. 4, filling of a liquid state transparent resin 142 that does not contain or slightly contains the light scatterer scattering the laser light 114 is performed through the resin filling hole 154 (filling step; semiconductor laser sealing step; wire sealing step). While the filling of the transparent resin 142 is performed, air in the recess part 120 below the cover 150 is discharged to the outside of the package 108 through the left exhaust hole 1521 and the right exhaust hole 152r. The transparent resin 142 after filling is a resin that forms the transparent resin layer 140.

As in part (d) of FIG. 4, the recess part 120 is filled with the liquid state transparent resin 142 until at least the liquid state transparent resin 142 comes into contact with the lower surface of the cover 150, and the hook part 158 is submerged in the liquid state transparent resin 142. The filling may be performed until the liquid state transparent resin 142 completely fills the left and right exhaust holes 1521 and 152r as in part (e) of FIG. 4. Alternatively, the filling may be performed to the extent that the liquid state transparent resin 142 partially fills the left and right exhaust holes 1521 and 152r as in an intermediate state between part (d) and part (e) of FIG. 4.

Next, the transparent resin 142 after filling is cured (curing step), and the transparent resin layer 140 is formed.

By such a method, the semiconductor laser 100 and the wires 110 are resin-sealed in the transparent resin layer 140. In addition, the transparent resin layer 140 is fixed to the cover 150 and the package 108, and the cover 150 is fixed to the package 108 through the transparent resin layer 140. A method for curing the liquid state transparent resin 142 may be thermal curing, photo-curing, or any method.

(Manufacturing Method)

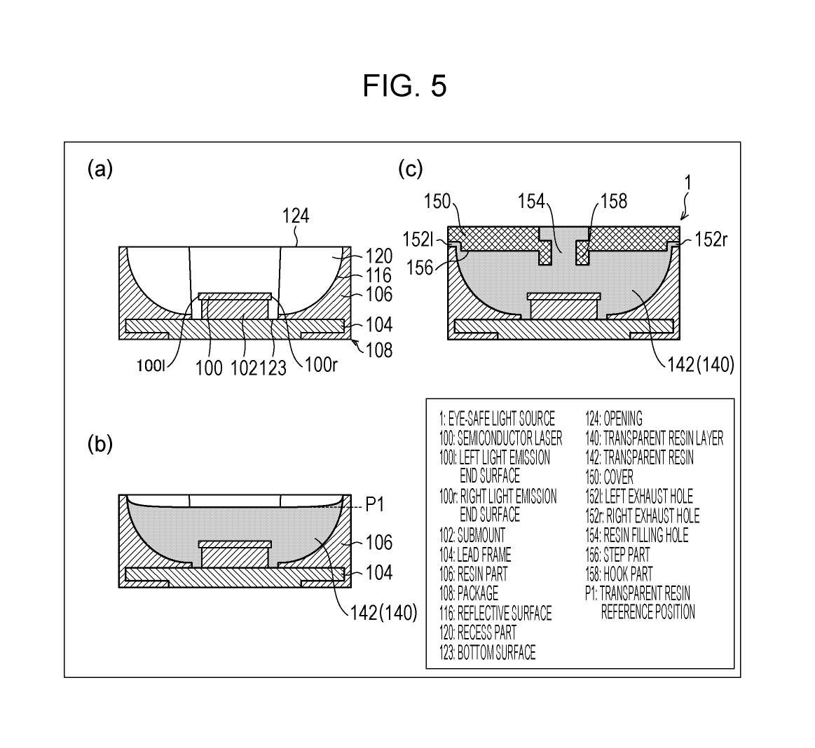

Hereinafter, another method (second manufacturing method) for manufacturing the eye-safe light source 1 will be described based on FIG. 5.

FIG. 5 is a view for describing the other method for manufacturing the eye-safe light source 1 illustrated in FIG. 1 in order. In FIG. 5, the wires 110 is not illustrated.

As in part (a) of FIG. 5, the semiconductor laser 100 is mounted through the submount 102 on the bottom surface 123 of the recess part 120 such that both light emission end surfaces 1001 and 100r face the reflective surface 116 (semiconductor laser mounting step). One wire 110 is connected to the semiconductor laser 100 and the lead frame 104, and another wire 110 is connected to the submount 102 and the lead frame 104 (connecting step).

Next, as in part (b) of FIG. 5, the recess part 120 of the package 108 is filled with the liquid state transparent resin 142 (first resin), which forms the transparent resin layer 140, to a transparent resin reference position (reference position) P1 (filling step; semiconductor laser sealing step; wire sealing step). The transparent resin reference position P1 is a reference position on the boundary surface of the transparent resin layer 140 on the opening 124 side (opposite side from the bottom surface 123). The transparent resin reference position P1 is determined in advance such that in a subsequent step, when the cover 150 is mounted on the upper surface of the package 108, the liquid state transparent resin 142 comes into contact with the lower surface of the step part 156 of the cover 150, and the hook part 158 of the cover 150 is submerged in the liquid state transparent resin 142. Furthermore, the transparent resin reference position P1 may be determined in advance such that when the cover 150 is mounted on the upper surface of the package 108, the liquid state transparent resin 142 completely fills the left and right exhaust holes 1521 and 152r. In addition, the filling reference position is preferably determined in advance such that when the cover 150 is mounted on the upper surface of the package 108, the liquid state transparent resin 142 does not overflow from the package 108 so that the liquid state transparent resin 142 does not contaminate the outer surface of the package 108.

Next, as in part (c) of FIG. 5, the cover 150 is mounted on the package 108 such that the step part 156 of the cover 150 fits in the opening 124 of the recess part 120, and the peripheral part 157 of the lower surface of the cover 150 comes into contact with the upper surface of the package 108 (lid mounting step). In the present manufacturing method, the cover 150 is mounted on the liquid state transparent resin 142 after filling. Thus, the left and right exhaust holes 1521 and 152r for discharging air, and the resin filling hole 154 for filling of the liquid state transparent resin 142 are not necessary. While the left and right exhaust holes 1521 and 152r and the resin filling hole 154 are not necessary, it is preferable that a hole (left and right exhaust holes 1521 and 152r; resin filling hole 154) that connects the inside of the recess part 120 to the outside of the package 108 through the cover 150 is present in order not to leave the void in the recess part 120 (between the transparent resin layer 140 and the cover 150).

Next, the liquid state transparent resin 142 that is in contact with the cover 150 is cured (curing step), and the transparent resin layer 140 is formed.

By such a method, the semiconductor laser 100 and the wires 110 are resin-sealed in the transparent resin layer 140. In addition, the transparent resin layer 140 is fixed to the cover 150 and the package 108, and the cover 150 is fixed to the package 108 through the transparent resin layer 140. A method for curing the liquid state transparent resin 142 may be thermal curing, photo-curing, or any method.

### Modification Example 1

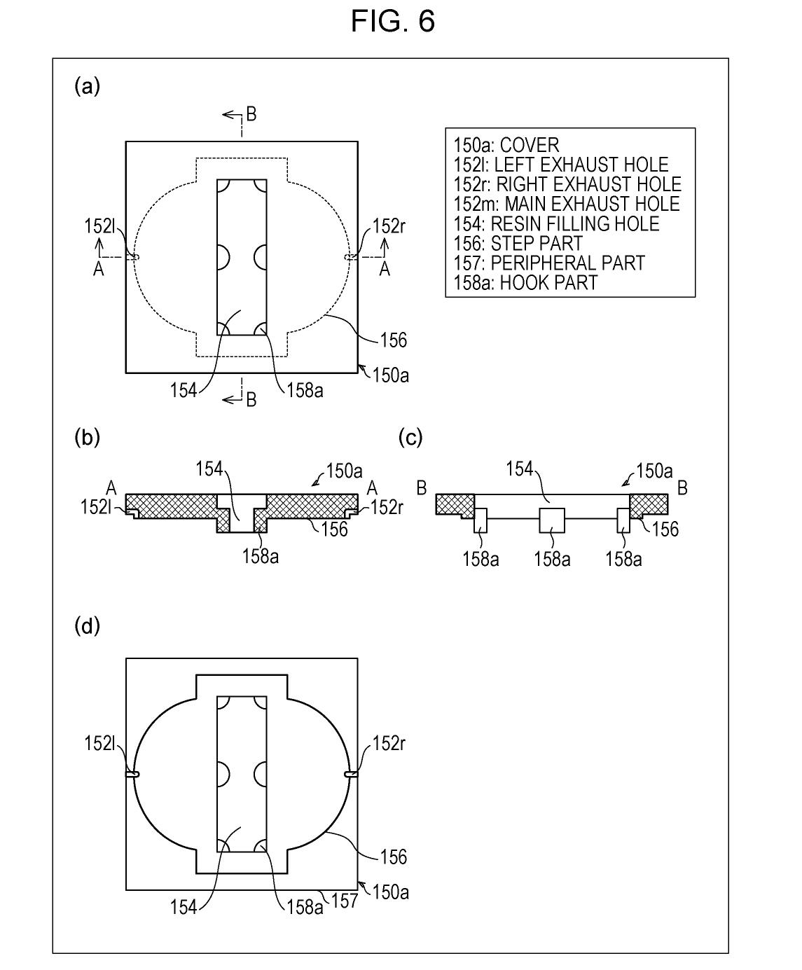

Hereinafter, a cover 150a that is Modification Example 1 of the cover 150 included in the eye-safe light source 1 according to Embodiment 1 will be described based on FIG. 6.

FIG. 6 is a view illustrating a schematic configuration of the cover 150a that is Modification Example 1 of the cover 150 illustrated in FIG. 3. Part (a) of FIG. 6 illustrates a top view. Part (b) of FIG. 6 illustrates an AA sectional view of part (a) of FIG. 6. Part (c) of FIG. 6 illustrates a BB sectional view of part (a) of FIG. 6. Part (d) of FIG. 6 illustrates a bottom view.

As illustrated in FIG. 6, the cover 150a of Modification Example 1 includes the left exhaust hole 1521, the right exhaust hole 152r, the resin filling hole 154, the step part 156, and a hook part 158a in the same manner as the above-described cover 150. The cover 150a that is Modification Example 1 is different from the above-described cover 150 in the hook part 158a.

In the above-described cover 150, the hook part 158 is contiguously disposed around the resin filling hole 154. In the cover 150a of the present modification example, a plurality of the hook parts 158a are non-contiguously disposed at the corners of the resin filling hole 154 and the centers of the long edges of the resin filling hole 154. The shape and the arrangement of the hook part are not limited, provided that the hook part reinforces the engagement between the cover 150 and the transparent resin layer 140, and the void does not remain in the recess part 120 below the cover 150.

### Modification Example 2

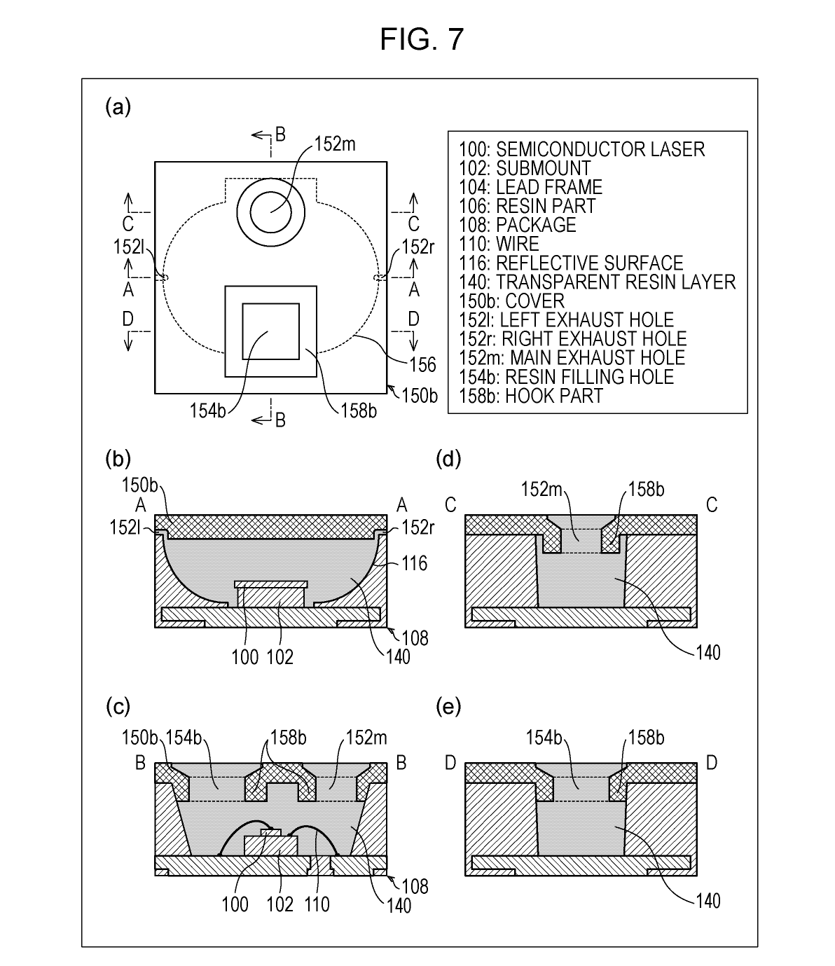

Hereinafter, a cover 150b that is Modification Example 2 of the cover 150 included in the eye-safe light source 1 according to Embodiment 1 will be described based on FIG. 7.

FIG. 7 is a view illustrating a schematic configuration of the cover 150b that is Modification Example 2 of the cover 150 illustrated in FIG. 3. Part (a) of FIG. 7 illustrates a top view of the cover 150b. Part (b) of FIG. 7 illustrates an AA sectional view of part (a) of FIG. 7 in the eye-safe light source 1 in which the cover 150b of Modification Example 2 is used. Part (c) of FIG. 7 illustrates a BB sectional view of part (a) of FIG. 7 in the eye-safe light source 1 in which the cover 150b of Modification Example 2 is used. Part (d) of FIG. 7 illustrates a CC sectional view of part (a) of FIG. 7 in the eye-safe light source 1 in which the cover 150b of Modification Example 2 is used. Part (e) of FIG. 7 illustrates a DD sectional view of part (a) of FIG. 7 in the eye-safe light source 1 in which the cover 150b of Modification Example 2 is used.

As illustrated in part (a) of FIG. 7, the cover 150b of Modification Example 2 includes the left exhaust hole 1521, the right exhaust hole 152r, the resin filling hole 154b, the step part 156, and a hook part 158b in the same manner as the above-described cover 150. Furthermore, the cover 150b of Modification Example 2 includes a main exhaust hole 152m for discharging air. The hook part 158b is formed in the main exhaust hole 152m.

The following two points are the differences between the cover 150b that is Modification Example 2 and the above-described cover 150. One point is that two through holes (a resin filling hole 154b and the main exhaust hole 152m) that pass from the lower surface to the upper surface of the cover 150b are included. One through hole (resin filling hole 154b) is used as a hole for filing of the resin, and the other through hole (main exhaust hole 152m) is used as a hole for discharging air. Another point is that the hook part 158b has an inclined surface as illustrated in FIG. 7.

As in Modification Example 2, including a plurality of through holes, and using at least one of the through holes as the resin filling hole for filling of the liquid state transparent resin 142 forming the transparent resin layer 140, and at least one of the other through holes as the exhaust hole for discharging air is preferable because the filling of the liquid state transparent resin 142 may be smoothly performed without being hindered by air in the recess part 120. Accordingly, the smooth filling of the liquid state transparent resin 142 may improve the productivity of the eye-safe light source 1.

In this case, since air has higher fluidity than the liquid state transparent resin 142, the opening area of the main exhaust hole 152m may be smaller than that of the resin filling hole 154b. In addition, in order to easily recognize the polarity of the eye-safe light source 1, the exhaust hole and the resin filling hole may have different shapes, and the exhaust hole and the resin filling hole may be used as a cathode mark and an anode mark.

### Modification Example 3

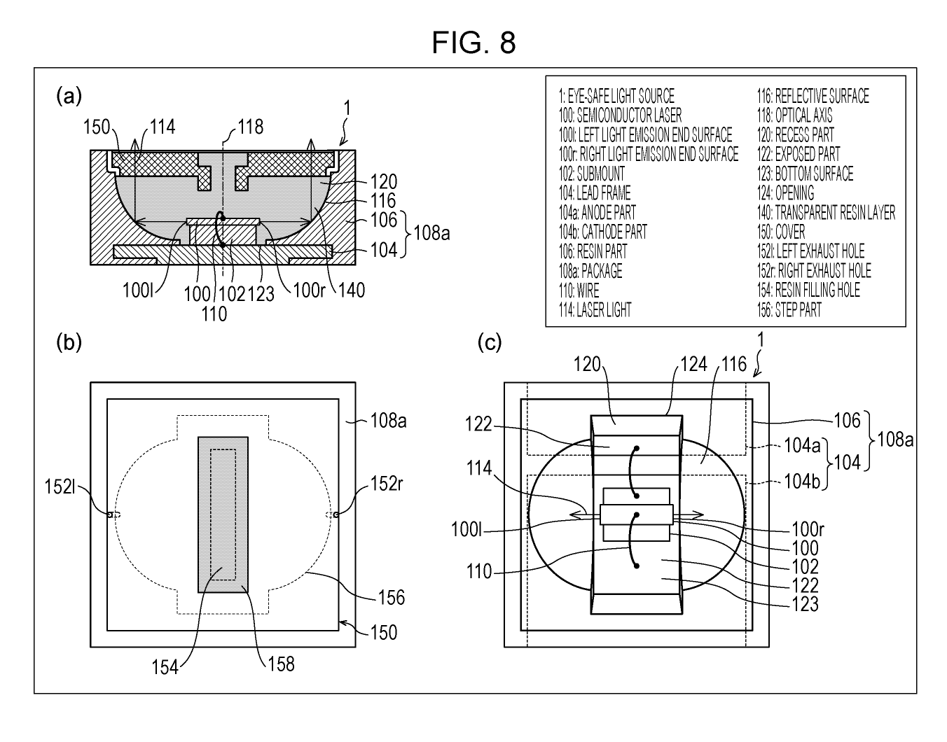

Hereinafter, a package 108 that is Modification Example 3 of the package 108 included in the eye-safe light source 1 according to Embodiment 1 will be described based on FIG. 8.

(Package)

FIG. 8 is a view illustrating a schematic configuration of the eye-safe light source 1 in which the package 108a that is Modification Example 3 of the package 108 illustrated in FIG. 2 is used. Part (a) and part (b) of FIG. 8 illustrate a sectional view and a top view of the eye-safe light source 1 in which the package 108a of Modification Example 3 is used. Part (c) of FIG. 8 illustrates a top view of the package 108a of Modification Example 3.

As illustrated in FIG. 8, the package 108a of Modification Example 3 is a member in which the surrounding area of the lead frame 104 is partially covered with the resin part 106 in the same manner as the above-described package 108. The semiconductor laser 100 is accommodated in the recess part 120.

The package 108a of Modification Example 3 is different from the above-described package 108 only in that the resin part 106 is extended until the upper surface of the cover 150 is positioned at the same height as the upper surface of the package 108a or below the upper surface of the package 108a.

By extending the resin part 106, the cover 150 is accommodated inside the package 108a and is protected from external force that is exerted sidewise (left-right direction in part (a) of FIG. 8; direction along the page of part (b) of FIG. 8). Thus, the cover 150 may be prevented from being separated from the package 108a by external force that is exerted sidewise.

However, by extending the resin part 106, the package 108a of Modification Example 3 has a larger size than the above-described package 108b. Thus, it is also preferable that the resin part 106 is not extended as in the above-described package 108.

In addition, the left exhaust hole 1521 and the right exhaust hole 152r of the cover 150 are open on the upper surface of the cover 150 to the outside of the eye-safe light source 1.

### Embodiment 2

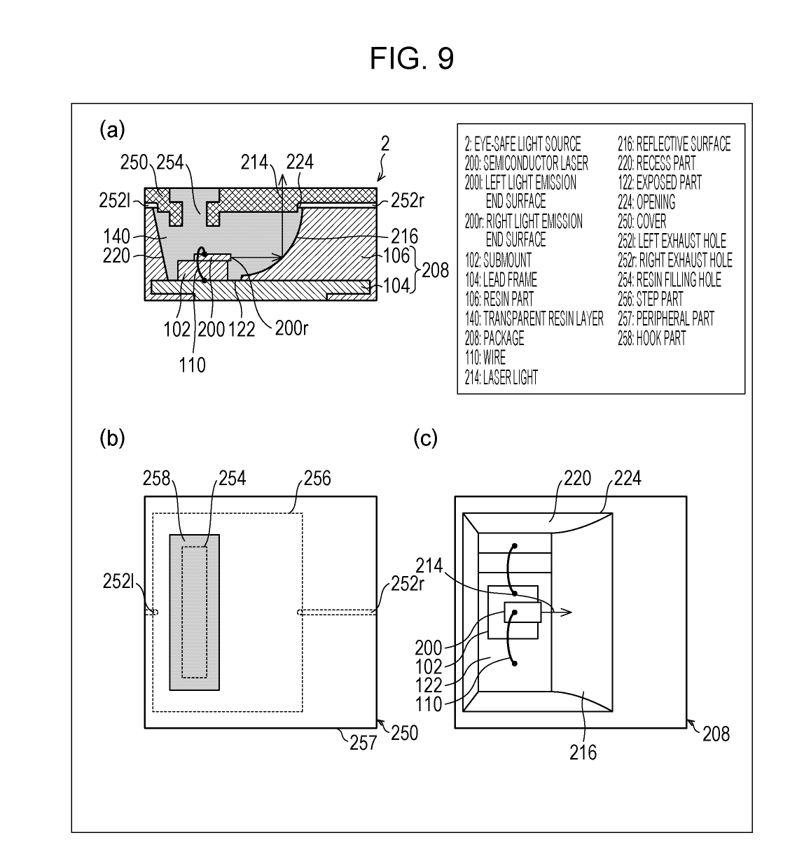

Another embodiment of the present invention will be described below based on FIG. 9. For convenience of description, members having the same function as the members described in the above embodiment will be designated by the same reference signs, and descriptions of such members will not be repeated.

FIG. 9 is a view illustrating a schematic configuration of an eye-safe light source 2 according to Embodiment 2 of the present invention. Part (a) of FIG. 9 illustrates a sectional view of the eye-safe light source 2. Part (b) of FIG. 9 illustrates a top view of the eye-safe light source 2. Part (c) of FIG. 9 illustrates a top view of the eye-safe light source 2 without a cover 250 and the transparent resin layer 140. Therefore, part (c) of FIG. 9 illustrates a schematic configuration of a package 208 included in the eye-safe light source, and a schematic arrangement of the semiconductor laser 100 with respect to the package 208. While a direction in which the eye-safe light source 2 radiates light from an opening 224 of a recess part 220 is an upward direction in the following description, the direction of the eye-safe light source 2 at the time of manufacturing, use, and the like is not limited thereto.

As illustrated in FIG. 9, the eye-safe light source 2 according to Embodiment 2 includes the semiconductor laser 200, the submount 102, the package 208 (container), the wires 110, the transparent resin layer 140, and the cover 250 (light scattering layer). The semiconductor laser 200 emits laser light 214 from only a right light emission end surface 200r. The semiconductor laser 200 is mounted on the submount 102. The recess part 220 is formed in the package 208. The wires 110 are connected to the semiconductor laser 200. The transparent resin layer 140 is configured by curing a liquid state resin with which the recess part 220 is filled. The cover 250 covers the opening 224 of the recess part 220.

The cover 250 of Embodiment 2 includes a left exhaust hole 2521 and a right exhaust hole 252r for discharging air, a resin filling hole 254 for filling of the liquid state resin forming the transparent resin layer 140, a step part 256 for fitting in the opening 224 of the recess part 220, and a hook part 258 for interlocking with the transparent resin layer 140 in the same manner as the cover 150 of above-described Embodiment 1. In addition, the cover 250 is formed in advance from a scattering resin that is configured by mixing, in a transparent resin (base material) through which the laser light 214 passes, a light scatterer which scatters the laser light 214. In addition, the cover 250 is mounted on the package 108 such that a peripheral part 257 outside the step part 256 comes into contact with the upper surface of the package 208, and the step part 256 fits in the opening 224 of the recess part 220.

The following three points are the differences between the eye-safe light source 1 according to above-described Embodiment 1 and the eye-safe light source 2 according to Embodiment 2.

One point is that while the semiconductor laser 100 emits the laser light 114 from the light emission end surfaces (the left light emission end surface 1001 and the right light emission end surface 100r) on both of the left and right sides in the eye-safe light source 1 according to Embodiment 1, the semiconductor laser 200 emits the laser light 214 from only the light emission end surface (right light emission end surface 200r) on the right side in the eye-safe light source 2 according to Embodiment 2.

Another point is that while the shape of the reflective surface 116 of the recess part 120 disposed in the package 108 is a part of a paraboloidal surface of revolution in the eye-safe light source 1 according to Embodiment 1, the shape of the reflective surface 216 of the recess part 220 disposed in the package 208 is a part of a curved surface acquired by translating a parabola in a direction perpendicular to a plane including the parabola in the eye-safe light source 2 according to Embodiment 2. In addition, only a side surface that faces the right light emission end surface 200r among the side surfaces of the recess part 120 is the reflective surface 216.

Another point is that the resin filling hole 254 of the cover 250 is disposed on the left side of the center of the cover 250 in order to be separated from the optical path of the laser light 214.

That is, the eye-safe light source 2 according to Embodiment 2 is different from the eye-safe light source 1 according to above-described Embodiment 1 in that the semiconductor laser 200 that emits the laser light 214 to only one side is used. Accordingly, the shapes of the recess part 220 and the cover 250 are different.

In the same manner as the eye-safe light source 1 that uses the symmetric semiconductor laser 100, the lifetime of the eye-safe light source 2 that uses the asymmetric semiconductor laser 200 may increase, and the cover 250 is not easily separated from the package 208. In addition, from the fail-safe safety philosophy, the eye-safe light source 2 secures eye safety and may be manufactured using the manufacturing method described in FIG. 4 or FIG. 5. In addition, the light distribution characteristics and the light polarization characteristics of the eye-safe light source 2 may be adjusted.

In addition, in the same manner as the package 108a of Modification Example 3 of above-described Embodiment 1, the resin part 106 may be extended in the package 208 of Embodiment 2.

### Embodiment 3

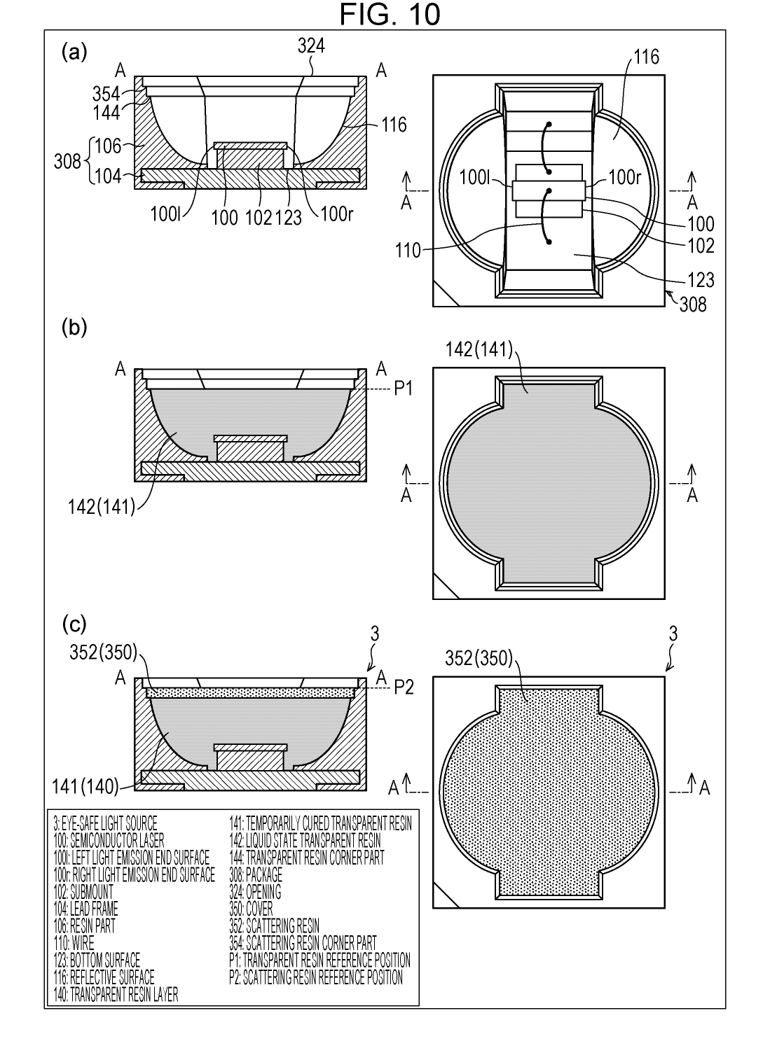

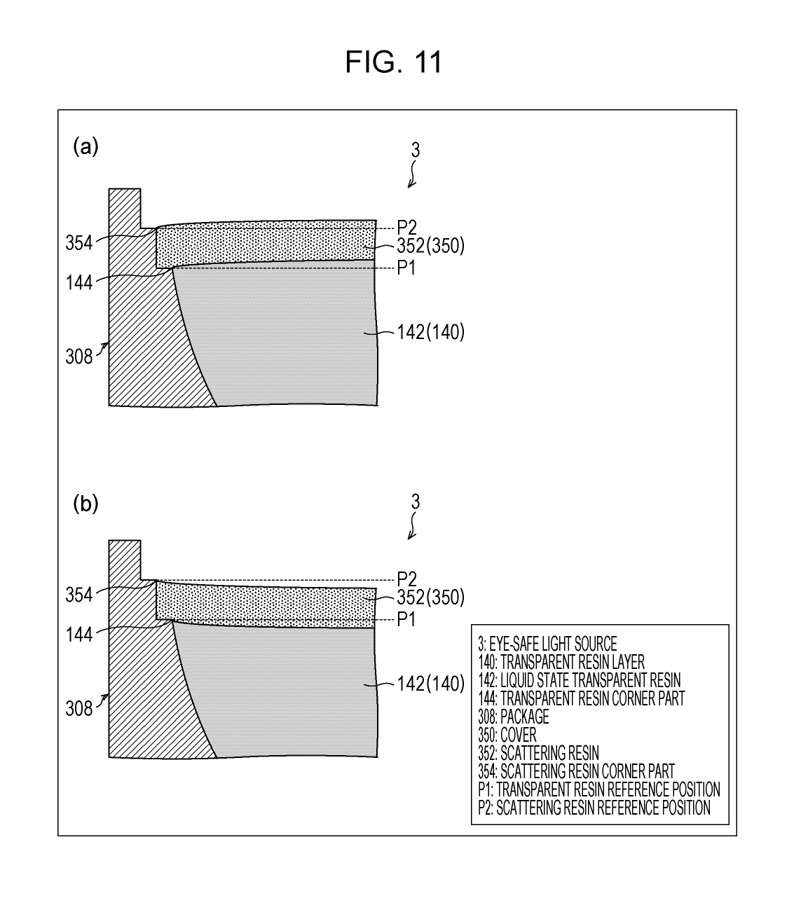

Another embodiment of the present invention will be described below based on FIG. 10 and FIG. 11. For convenience of description, members having the same function as the members described in the above embodiment will be designated by the same reference signs, and descriptions of such members will not be repeated.

In above-described Embodiments 1 and 2, the covers 150 and 250 that are formed in advance are mounted on the packages 108 and 208, and are fixed to the packages 108 and 208 through the transparent resin layer 140 (first or second manufacturing method). In Embodiment 3, filling of a liquid state scattering resin 352 (second resin) that forms a cover 350 is directly performed on a transparent resin 141 that forms the transparent resin layer 140 and is temporarily cured, and the liquid state scattering resin 352 is cured along with the temporarily cured transparent resin 141 (third manufacturing method). Accordingly, the cover 350 is formed along with the transparent resin layer 140 at the same time as a single body.

(Package)

A package 308 in Embodiment 3 is different from the package 108 in above-described Embodiment 1 only in that a transparent resin corner part 144 (first corner part) and a scattering resin corner part 354 (second corner part) are included in a recess part 320.

The transparent resin corner part 144 is disposed at the predetermined transparent resin reference position P1 (reference position) to which the filling of the liquid state transparent resin 142 forming the transparent resin layer 140 is performed. The transparent resin reference position P1 is a reference position on the boundary surface of the transparent resin layer 140 on an opening 324 side (opposite side from the bottom surface 123). The scattering resin corner part 354 is disposed at a predetermined scattering resin reference position P2 (reference position) to which the filling of the liquid state scattering resin 352 forming the cover 350 is performed. The scattering resin reference position P2 is a reference position on the boundary surface of the lid 350 on the opening 324 side.

(Manufacturing Method)

Hereinafter, a method (third method) for manufacturing the eye-safe light source 3 according to Embodiment 3 will be described based on FIG. 10 and FIG. 11.

FIG. 10 is a view for describing the method for manufacturing the eye-safe light source 3 according to Embodiment 3. A view on the right side of each of Parts (a) to (c) of FIG. 10 illustrates a top view, and a view on the left side of each of Parts (a) to (c) of FIG. 10 illustrates an AA sectional view of the view on the right side. In FIG. 10, the wires 110 are not illustrated.

As in part (a) of FIG. 10, the semiconductor laser 100 is mounted through the submount 102 on the bottom surface 123 of the recess part 320 such that both light emission end surfaces 1001 and 100r face the reflective surface 116 (semiconductor laser mounting step). Two wires 110 are connected to the semiconductor laser 100 and the submount 102, and the lead frame 104 (connecting step).

Next, as in part (b) of FIG. 10, the recess part 320 of the package 308 is filled with the liquid state transparent resin 142 to the transparent resin reference position P1 (filling step; semiconductor laser sealing step; wire sealing step). At this point, the semiconductor laser 100 and the wires 110 are sealed in the transparent resin 142.

In a subsequent step, the liquid state transparent resin 142 forming the transparent resin layer 140 is temporarily incompletely cured so that the liquid state scattering resin 352 is not mixed with the liquid state transparent resin 142 at the time of the filling of the liquid state scattering resin 352 forming the cover 350, and the temporarily cured transparent resin 141 is formed (temporarily curing step). In this stage, in a case where the liquid state transparent resin 142 forming the transparent resin layer 140 is completely cured, the fixing between the transparent resin layer 140 and the cover 350 in the completed eye-safe light source 3 is weak. Therefore, the liquid state transparent resin 142 is not to be excessively cured. In addition, the liquid state scattering resin 352 is a resin configured by mixing the light scatterer scattering the laser light 114 in the transparent resin (base material) through which the laser light 114 is transmitted.

Next, as in part (c) of FIG. 10, the recess part 320 of the package 308 is further filled with the liquid state scattering resin 352, which forms the cover 350, to the scattering resin reference position P2 on the temporarily cured transparent resin 141 (refilling step).

The liquid state scattering resin 352 and the temporarily cured transparent resin 141 are completely cured together at the same time (main curing step). Accordingly, since the scattering resin 352 and the transparent resin 141 are cured as a single body, a risk that only the cover 350 is detached from the package 308 by separation between the cover 350 and the transparent resin layer 140 may be reduced. According to the present manufacturing method, the cover 350 does not need the exhaust hole for discharging air and the resin filling hole for filling of the liquid state transparent resin 142 forming the transparent resin layer 140.

By such a method, the semiconductor laser 100 and the wires 110 are resin-sealed in the transparent resin layer 140. In addition, the transparent resin layer 140 is fixed to the cover 350 and the package 308, and the cover 350 is fixed to the package 308 through the transparent resin layer 140. A method for curing the liquid state transparent resin 142 may be thermal curing, photo-curing, or any method.

(Base Material and Scatterer)

The liquid state scattering resin 352 forming the cover 350 preferably has a high affinity with the liquid state transparent resin 142 forming the transparent resin layer 140 so that the cover 350 and the transparent resin layer 140 are sufficiently integrated. In order to achieve a high affinity, the base material of the liquid state scattering resin 352 forming the cover 350 is preferably the same kind of resin as the base material (the transparent resin 142 in a case where the transparent resin 142 does not contain the light scatterer) of the liquid state transparent resin 142 forming the transparent resin layer 140.

For example, the base materials of the scattering resin 352 and the transparent resin 142 are preferably methyl-based silicon resins represented by a dimethyl silicone resin. In this case, since the base materials of the scattering resin 352 and the transparent resin 142 are the same kind of resin, the cover 350 and the transparent resin layer 140 are strongly fixed to each other and sufficiently integrated.

In addition, for example, it is preferable that the base material of the scattering resin 352 is a phenyl-based silicone resin, and the base material of the transparent resin 142 is a methyl-based silicone resin. Generally, the phenyl-based silicone resin represented by a methyl phenyl silicone resin has a higher gas blocking ability and higher hardness of the resin after curing than the methyl-based silicone resin represented by the dimethyl silicone resin. Thus, in a case where the transparent resin layer 140 that directly seals a semiconductor laser element is formed of the transparent resin 142 with the base material of the methyl-based silicone resin that is relatively soft after curing, and the cover 350 on the outer side is formed of the scattering resin 352 with the base material of the phenyl-based silicone resin that has an excellent gas blocking ability, a surface-mount eye-safe laser light source that has a long lifetime and an excellent gas blocking ability may be implemented. In addition, since the phenyl-based silicone resin and the methyl-based silicone resin are silicone-based resins, the cover 350 and the transparent resin layer 140 are sufficiently strongly fixed to each other and integrated.

In addition, for example, the base materials of the scattering resin 352 and the transparent resin 142 are preferably phenyl-based silicone resins. In this case, care needs to be taken on the hardness after the main curing step. The scattering resin 352 and the transparent resin 142 are preferably adjusted such that the cover 350 and the transparent resin layer 140 are flexible. Accordingly, a surface-mount eye-safe laser light source that has a long lifetime and an excellent gas blocking ability may be implemented.

The present invention is not limited to such a configuration. Different kinds of resins may be used for the base material of the scattering resin 352 and the base material of the transparent resin 142, provided that cure inhibition does not occur. In addition, it is important that the transparent resin layer 140 that directly seals the semiconductor laser element has higher flexibility after curing than the cover 350 on the outer side. Thus, in the case of mixing the light scatterer in each of the scattering resin 352 and the transparent resin 142, it is preferable that the light scatterer is mixed in the transparent resin 142 forming the transparent resin layer 140 at a lower concentration than in the scattering resin 352 forming the cover 350. In addition, in order to cause a local increase in temperature in the vicinity of the left and right light emission end surfaces 1001 and 100r of the semiconductor laser 100, it is preferable that the concentration at which the light scatterer is mixed in the transparent resin 142 forming the transparent resin layer 140 is low. It is further preferable that the light scatterer is not mixed in the transparent resin 142.

(Error in Filling Amount)

Furthermore, as will be described below, the eye-safe light source 3 according to Embodiment 3 may suppress a manufacturing error caused by an error in the filling amount of the liquid state transparent resin 142 and the filling amount of the scattering resin 352.

Filling of a desired amount of the liquid state transparent resin 142 and a desired amount of the scattering resin 352 is performed using a capacity measuring dispenser in order to fill the recess part 120 to the predetermined transparent resin reference position P1 and the scattering resin reference position P2. The filling amount of the transparent resin 142 and the filling amount of the scattering resin 352 include errors. In a case where the size of the eye-safe light source 3 is small, even a minute error has a significant effect.

FIG. 11 is an enlarged view for describing a case where the filling amount of the liquid state transparent resin 142 forming the transparent resin layer 140 and the filling amount of the liquid state scattering resin 352 forming the cover 350 are (a) excessively large or (b) excessively small in the method for manufacturing the eye-safe light source 3 illustrated in FIG. 10.

The transparent resin corner part 144 reduces the error in the filling amount of the transparent resin 142 by surface tension in a case where the filling amount of the liquid state transparent resin 142 is excessively large or excessively small, and maintains the shape of the transparent resin 142. Similarly, the scattering resin corner part 354 reduces the error in the filling amount of the scattering resin 352 by surface tension in a case where the filling amount of the liquid state scattering resin 352 is excessively large or excessively small, and maintains the shape of the scattering resin 352.

Accordingly, a distortion and a positional deviation of the transparent resin layer 140 and the cover 350 caused by the error in filling amount are suppressed. Thus, a manufacturing error in the light distribution characteristics of the eye-safe light source 3 is suppressed.

In the same manner as the eye-safe light source 1 in which the cover 150 is formed in advance, the lifetime of the eye-safe light source 3 in which the cover 350 is not formed in advance may increase, and the cover 350 is not easily separated from the package 308. In addition, from the fail-safe safety philosophy, the eye-safe light source 3 secures eye safety, and the light distribution characteristics and the light polarization characteristics of the eye-safe light source 3 may be adjusted.

In addition, in the same manner as the eye-safe light source 3, an eye-safe light source may be manufactured by adding the transparent resin corner part 144 and the scattering resin corner part 354 to the package 208 corresponding to the semiconductor laser 200 that emits the laser light 214 to only one side.

### Embodiment 4

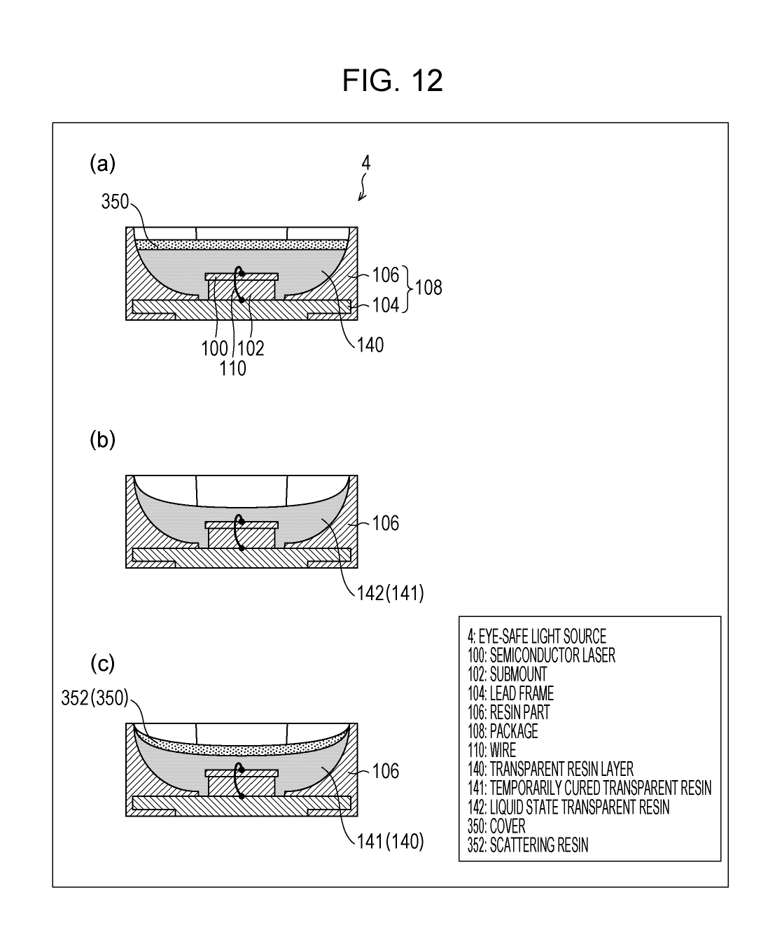

Another embodiment of the present invention will be described below based on FIG. 12. For convenience of description, members having the same function as the members described in the above embodiment will be designated by the same reference signs, and descriptions of such members will not be repeated.

An eye-safe light source 4 according to Embodiment 4 is different from the eye-safe light source 3 according to above-described Embodiment 3 only in that the package 108 in which the transparent resin corner part 144 and the scattering resin corner part 354 are not present is included in the eye-safe light source 4. That is, in Embodiment 4, the recess part 120 in which the transparent resin corner part 144 and the scattering resin corner part 354 are not present is filled with the transparent resin 142, and filling of the liquid state scattering resin 352 forming the cover 350 is directly performed on the temporarily cured transparent resin 142 (third manufacturing method).

(Creeping Up)

FIG. 12 is a sectional view for describing the eye-safe light source 4 according to Embodiment 4. Part (a) of FIG. 12 illustrates an ideal sectional shape of the eye-safe light source 4. Part (b) of FIG. 12 illustrates creeping up of the liquid state transparent resin 142 forming the transparent resin layer 140. Part (c) of FIG. 12 illustrates creeping up of the liquid state scattering resin 352 forming the cover 350.

Resins that have an affinity with the resin part 106 are used as the liquid state transparent resin 142 forming the transparent resin layer 140 and the liquid state scattering resin 352 forming the cover 350 in order to fix the liquid state transparent resin 142 and the liquid state scattering resin 352 to the package 108. The affinity causes the liquid state transparent resin 142 and the scattering resin 352 to creep up on the resin part 106 by surface tension.

The recess part 120 is filled with the liquid state transparent resin 142 forming the transparent resin layer 140 (filling step). At this point, as in part (b) of FIG. 12, since the liquid state transparent resin 142 creeps up on the resin part 106, the liquid state transparent resin 142 has a shape of which the center is recessed. The recessed shape of the transparent resin 142 depends on the surface tension and thus, is unstable and changes each time the filling of the transparent resin 142 is performed.

Next, the transparent resin 142 is temporarily cured (temporary curing step), and the filling of the liquid state scattering resin 352 forming the cover 350 is performed on the temporarily cured transparent resin 141 (scattering resin filling step). At this point, as in part (c) of FIG. 12, since the liquid state scattering resin 352 creeps up on the resin part 106, the scattering resin 352 is formed in a shape of which the center is recessed. In addition, since the filling of the liquid state scattering resin 352 is performed on the temporarily cured transparent resin 141 having an unstable recessed shape, the liquid state scattering resin 352 has a non-uniform thickness, and the peripheral part of the scattering resin 352 is thin. The recessed shape of the scattering resin 352 depends on the surface tension and thus, is unstable and changes each time the filling of the scattering resin 352 is performed.

The liquid state scattering resin 352 and the temporarily cured transparent resin 141 are completely cured together (main curing step). Accordingly, as in part (c) of FIG. 12, the transparent resin layer 140 having a recessed shape and the cover 350 are formed as a single body.

Therefore, since the shape of the transparent resin layer 140 and the shape and the thickness of the cover 350 are non-uniform, a manufacturing error occurs in the shape of the eye-safe light source 4 according to Embodiment 4. Such a manufacturing error in shape affects the optical path of the laser light 114 and making the laser light 114 eye-safe. Thus, a manufacturing error occurs in the light distribution characteristics and the eye safety of the eye-safe light source 4.

The above-described effect of the creeping up of the liquid state transparent resin 142 and the scattering resin 352 is significant in a case where the size of the eye-safe light source 4 is small, because the surface tension is a force that noticeably works at a small scale level. Furthermore, as the size of the eye-safe light source 4 is decreased, the ratio of the peripheral part that is affected by the surface tension in the transparent resin 142 and the scattering resin 352 increases, and the laser light 114 is transmitted through the peripheral part that is affected by the surface tension. Thus, in a case where the size of the eye-safe light source 4 is small, particularly, in a case where the size of the eye-safe light source 4 is small within 5 mm×5 mm in a top view, the manufacturing error in the light distribution characteristics and the eye safety of the eye-safe light source 4 is noticeable.

Meanwhile, the eye-safe light source 3 according to above-described Embodiment 3 may stop the creeping up of the transparent resin 142 and the scattering resin 352 respectively at the transparent resin reference position P1 and the scattering resin reference position P2 using the transparent resin corner part 144 and the scattering resin corner part 354. Thus, in above-described Embodiment 3, the shape of the transparent resin layer 140 and the shape and the thickness of the cover 350 are stable. Therefore, the eye-safe light source 3 according to above-described Embodiment 3 may suppress the manufacturing error caused by the creeping up of the transparent resin 142 and the scattering resin 352.

Therefore, in order to suppress the manufacturing error in light distribution characteristics and eye safety, the eye-safe light source 3 according to above-described Embodiment 3 in which the transparent resin corner part 144 and the scattering resin corner part 354 are disposed is more preferable than the eye-safe light source 4 according to Embodiment 4. Furthermore, a manufacturing error in the covers 150 and 250 that scatter the laser light 114 and the laser light 214 is small in the eye-safe light sources 1 and 2 according to above-described Embodiments 1 and 2 in which the covers 150 and 250 are formed in advance in a predetermined shape. Thus, the eye-safe light sources 1 and 2 are further preferable.

The lifetime of the eye-safe light source 4 in which the transparent resin corner part 144 and the scattering resin corner part 354 are not disposed may also increase, and the cover 350 is not easily separated from the package 108 in the same manner as the eye-safe light source 3 according to above-described Embodiment 3 in which the transparent resin corner part 144 and the scattering resin corner part 354 are disposed. In addition, from the fail-safe safety philosophy, the eye-safe light source 4 secures eye safety, and the light distribution characteristics and the light polarization characteristics of the eye-safe light source 4 may be adjusted.

In addition, in the same manner as the eye-safe light source 4, an eye-safe light source may be manufactured with the package 208 corresponding to the semiconductor laser 200 that emits the laser light 214 to only one side.

### Embodiment 5

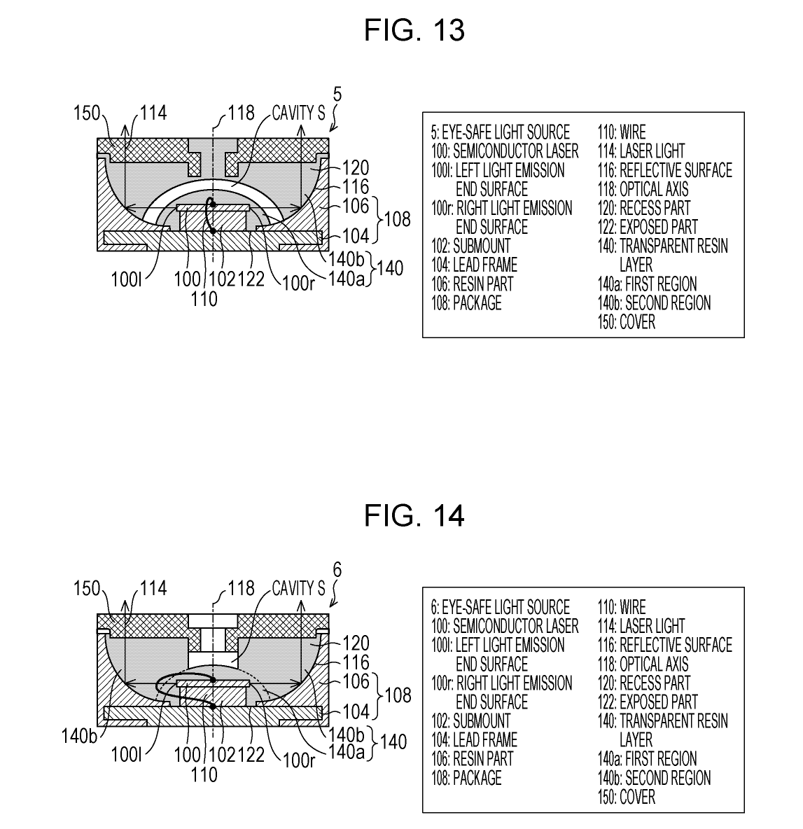

Another embodiment of the present invention will be described below based on FIG. 13. For convenience of description, members having the same function as the members described in the above embodiment will be designated by the same reference signs, and descriptions of such members will not be repeated.

In above-described Embodiments 1 to 4, while the transparent resin layer 140 occupies the whole inside of the recess parts 120, 220, and 320 below the covers 150, 250, and 350, the transparent resin layer 140 may occupy only a part of the inside of the recess parts 120, 220, and 320.

FIG. 13 is a sectional view illustrating a schematic configuration of an eye-safe light source 5 according to Embodiment 5 of the present invention.

The eye-safe light source 5 according to Embodiment 5 is different from above-described Embodiment 1 only in that the transparent resin layer 140 occupies only a part of the inside of the recess part 120, and a cavity S is present in the recess part 120. In other words, above-described Embodiment 1 is different from Embodiment 5 only in that the cavity S is not present, and a first region 140a and a second region 140b are integrated.

In Embodiment 5, the transparent resin layer 140 includes the first region 140a and the second region 140b that are separated from each other by the cavity S. In other words, in the eye-safe light source 1 according to above-described Embodiment 1, the cavity S is not present in the recess part 120, and the first region 140a and the second region 140b are integrated. Instead of the cavity S, another resin layer or the like may be formed between the first region 140a and the second region 140b.

The first region 140a of the transparent resin layer 140 resin-seals the semiconductor laser 100, and the semiconductor laser 100 and the wires 110.

The second region 140b of the transparent resin layer 140 is fixed in contact with the whole region of the lower surface of the cover 150 on the inner side of the step part 156. Furthermore, the second region 140b interlocks with the hook part 158 of the cover 150 and preferably fills the left and right exhaust holes 1521 and 152r and the resin filling hole 154. Accordingly, the second region 140b of the transparent resin layer 140 strongly engages with the cover 150 as a single body by a wide fixing area and an interlocking structure.

Therefore, regardless of whether the first region 140a in which the transparent resin layer 140 seals the semiconductor laser 100 is separated from or integrated with the second region in which the cover 150 is fixed to the package 108, and regardless of whether the transparent resin layer 140 occupies the whole or only a part of the inside of the recess part 120, the lifetime of the eye-safe light source 5 may increase, and the cover 350 is not easily separated from the package 308 in the same manner as the eye-safe light source 1.

In addition, in the package 208 corresponding to the semiconductor laser 200 that emits the laser light 214 to only one side, the transparent resin layer 140 may be formed in only a part of the inside of the recess part 220. In addition, in the manufacturing method in which the cover 350 is formed on the resin forming the transparent resin layer 140 without forming the cover 350 in advance, the transparent resin layer 140 may be formed in only a part of the inside of the recess part 320.

In addition, in the same manner as the package 108a of Modification Example 3 of above-described Embodiment 1, the resin part 106 may be extended in the package 108 of Embodiment 5.

### Embodiment 6

Another embodiment of the present invention will be described below based on FIG. 14. For convenience of description, members having the same function as the members described in the above embodiment will be designated by the same reference signs, and descriptions of such members will not be repeated.

FIG. 14 is a sectional view illustrating a schematic configuration of an eye-safe light source 6 according to Embodiment 6 of the present invention.

The eye-safe light source 6 according to Embodiment 6 is different from above-described Embodiment 1 only in that the transparent resin layer 140 occupies only a part of the inside of the recess part 120, and the cavity S is present in the recess part 120. Instead of the cavity S, another resin layer or the like may be formed.

In above-described Embodiment 5, the transparent resin layer 140 occupies only a part of the inside of the recess part 120 below the cover 150. However, the structure of the transparent resin layer 140 in above-described Embodiment 5 poses the following problems.

One problem is that since the first region 140a and the second region 140b are completely separated from each other, and the wires 110 are sealed in only the first region 140a, the wires 110 are not broken when the cover 150 is separated from the package 108. Thus, from the fail-safe safety philosophy, eye safety is not secured. In addition, in a case where the wires 110 pass through the second region 140b in order to secure eye safety, the wires 110 pass through a boundary surface between the first region 140a and the cavity S and a boundary surface between the second region 140b and the cavity S. Thus, the wires 110 are easily broken in a state where the transparent resin layer 140 is fixed to the package 108.

Another problem is that since the laser light 114 passes through the boundary surface between the first region 140a and the cavity S and the boundary surface between the second region 140b and the cavity S, refraction and reflection occur in the boundary surfaces, and optical designing for designing the light distribution characteristics and the light polarization characteristics of the eye-safe light source 5 is not easy. In addition, in order to implement the light distribution characteristics and the light polarization characteristics in the optical designing, the shapes of both boundary surfaces need to be accurately reproduced. Thus, the productivity of the eye-safe light source 5 is decreased.

Therefore, even in a case where the transparent resin layer 140 occupies only a part of the inside of the recess part 120, as illustrated in FIG. 14, it is preferable that the first region 140a and the second region 140b of the transparent resin layer 140 are contiguous so that the laser light 114 may reach the cover 150 from the left and right light emission end surfaces 1001 and 100r without passing through the boundary surfaces, and the wires 110 may pass through the second region 140b in which the cover 150 is fixed, without passing through the boundary surfaces.

Specifically, the transparent resin layer 140 is preferably formed at a position (on the optical path) through which at least the laser light 114 passes in the recess part 120. At least part of the wires 110 preferably passes through a part of the transparent resin layer 140 that is separated from the package 108 along with the cover 150 in a case where the cover 150 is separated from the package 108.

Accordingly, the lifetime of the eye-safe light source 6 in which the transparent resin layer 140 occupies only a part of the inside of the recess part 120 may increase, and the cover 150 is not easily separated from the package 108, in the same manner as the eye-safe light source 1 in which the transparent resin layer 140 occupies the whole inside of the recess part 120. In addition, from the fail-safe safety philosophy, the eye-safe light source 6 secures eye safety, and the light distribution characteristics and the light polarization characteristics of the eye-safe light source 6 may be adjusted.

Furthermore, the cavity S absorbs thermal expansion and thermal contraction of the transparent resin layer 140 and reduces stress generated in the transparent resin layer 140 by a change in temperature. Thus, stress exerted on the semiconductor laser 100 is reduced.

In addition, in the package 208 corresponding to the semiconductor laser 200 that emits the laser light 214 to only one side, the transparent resin layer 140 may be formed in only a part of the inside of the recess part 220. In addition, in the manufacturing method in which the cover 350 is formed on the resin forming the transparent resin layer 140 without forming the cover 350 in advance, the transparent resin layer 140 may be formed in only a part of the inside of the recess part 320.

In addition, in the same manner as the package 108a of Modification Example 3 of above-described Embodiment 1, the resin part 106 may be extended in the package 108 of Embodiment 6.

### Embodiment 7

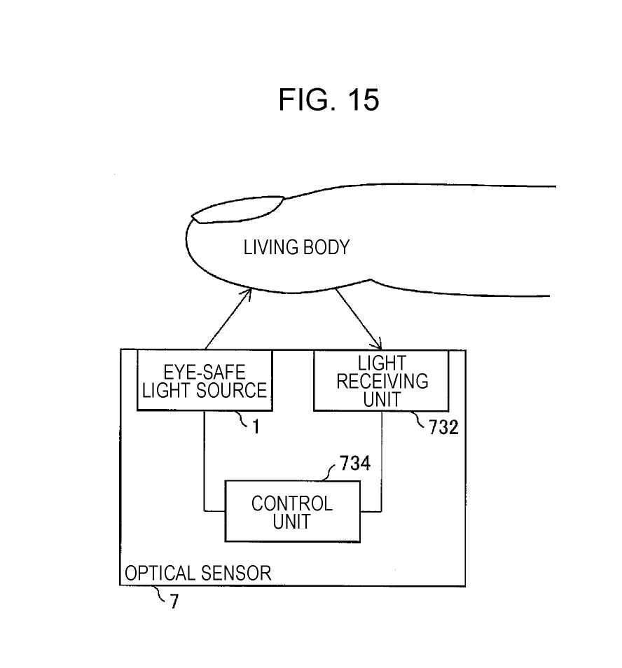

Another embodiment of the present invention will be described below based on FIG. 15. For convenience of description, members having the same function as the members described in the above embodiment will be designated by the same reference signs, and descriptions of such members will not be repeated.

FIG. 15 is a view illustrating a schematic configuration of an optical sensor 7 according to Embodiment 7 of the present invention.

As illustrated in FIG. 15, the optical sensor (electronic device) 7 includes the eye-safe light source 1 according to Embodiment 1, a light receiving unit 732, and a control unit 734. The light receiving unit 732 receives reflective light from a living body. The control unit 734 controls the eye-safe light source 1 and the light receiving unit 732.

The light receiving unit 732 may be disposed in the package 108 in the same manner as the eye-safe light source 1. The light receiving unit 732 may be disposed separately from the eye-safe light source 1.

The control unit 734 may be a semiconductor element that is disposed inside the package 108. That is, the control unit 734 may be a semiconductor element that is joined to the lead frame 104 and resin-sealed with the resin part 106. The control unit 734 may be disposed separately from the eye-safe light source 1.

Eye-safe light radiated from the eye-safe light source 1 is reflected by the living body, and the reflective light reflected by the living body is received by the light receiving unit 732. The control unit 734 calculates information related to the living body that reflects the eye-safe light, by comparing the eye-safe light radiated from the eye-safe light source 1 with the reflective light received by the light receiving unit 732.

Since the eye-safe light source 1 is a surface-mount light source that is appropriate for thinning, the optical sensor 7 is thin. There are multiple types of biometric information that may be collected using the eye-safe light source 1 as a light source, such as an iris, a vein in a finger, a palm, and the like, a fingerprint, and a palm print. The eye-safe light source 1 is effectively used in order to implement biometric authentication using the biometric information in a portable electronic device. The use of the eye-safe light source 1 is not limited to the portable electronic device. The eye-safe light source 1 may be used as a light source of a general fixed electronic device such as an automated teller machine (ATM), an electronic lock safe, and an electronic key for a vehicle or a house.

Since thinning is required for a wide range of electronic devices, the application of the eye-safe light source 1 is not limited to biometric authentication. The eye-safe light source 1 may be used in a light projecting device, a projector, an infrared camera light source, a motion sensor light source, a small electronic device, a portable electronic device, and the like. The small surface-mount eye-safe light source may also be effectively used in a communication device such as an electronic device that needs to be optically coupled to an optical fiber.

In addition, the method for fixing the covers 150, 150, 150a, 150b, and 250 (lids) illustrated in above-described Embodiments 1 to 6 may be widely applied to a surface-mount light source and a laser light source other than the eye-safe light source. Particularly, in the field of optical communication and optical communication devices, while such a light source is generally used in a closed space in a device without outputting light to living space, those skilled in the art will perceive that the same fixing method may be effectively used for a general transparent cover of a light source that does not particularly need eye safety.

### CONCLUSION

An eye-safe light source (1 to 6) according to Aspect 1 of the present invention is configured to include a semiconductor laser (100 and 200) that emits laser light (114 and 214); a container (the packages 108, 108a, 208, and 308 in which the recess parts 120, 220, and 320 are disposed) that includes a bottom surface (123) on which the semiconductor laser is mounted, a reflective surface (116 and 216) on which the laser light is reflected, and an opening (124, 224, and 324) through which the reflected laser light is radiated; a lid (covers 150, 250, and 350) that covers at least part of the opening; and a sealing resin (transparent resin layer 140) that is disposed in the container, seals the semiconductor laser, and fixes the lid to the container.

According to the above configuration, the lid is fixed to the container through the sealing resin in the container. Thus, at least part of a surface that is in contact with the sealing resin, that is, a region of the surface of the lid that faces the opening, contributes to the fixing of the lid to the container. Accordingly, the lid is not easily separated from the container, and a loss of eye safety caused by the separation of the lid from the eye-safe light source is prevented.

An eye-safe light source (1 to 6) according to Aspect 2 of the present invention may be configured such that in Aspect 1, the lid (covers 150, 250, and 350) scatters the laser light (114 and 214) and is disposed on at least an optical path of the laser light in the opening (124, 224, and 324).

According to the above configuration, the laser light radiated from the opening always passes through the lid, and the lid scatters the laser light. Thus, the laser light is made eye-safe.

An eye-safe light source (1 to 4 and 6) according to Aspect 3 of the present invention may be configured such that in Aspect 1 or 2, the sealing resin (transparent resin layer 140) is formed on at least an optical path of the laser light in the container (the recess parts 120, 220, and 320 disposed in the packages 108, 108a, 208, and 308).

According to the above configuration, since the sealing resin is formed on the optical path of the laser light, the laser light passes through the sealing resin without passing through a boundary surface until the laser light is incident on the lid after being emitted from the semiconductor laser. Accordingly, optical designing of the eye-safe light source 1 is easy.

An eye-safe light source (1 to 6) according to Aspect 4 of the present invention may be configured such that in any one aspect of Aspects 1 to 3, a wire (110) that is joined to the semiconductor laser (100 and 200) is sealed in the sealing resin (transparent resin layer 140).

According to the above configuration, since the wire is sealed in the sealing resin, the wire does not pass through a boundary of the sealing resin where the effect of thermal expansion and thermal contraction is significant. Thus, the wire is not easily broken, and defects of the eye-safe light source caused by a breakage of the wire may be reduced.

An eye-safe light source (1 to 4 and 6) according to Aspect 5 of the present invention may be configured such that in Aspect 4, engagement between the sealing resin (transparent resin layer 140) and the lid (covers 150, 250, and 350) is stronger than engagement between the sealing resin and the container (packages 108, 108a, 208, and 308).

According to the above configuration, the sealing resin that seals the wire engages with the lid more strongly than with the container. Thus, in a case where the lid is separated from the container, the sealing resin is separated from the container along with the lid and breaks the wire. Therefore, even in a case where the lid is separated from the eye-safe light source, the breakage of the wire stops the semiconductor laser from emitting the laser light. Thus, the eye safety of the eye-safe light source is maintained.

An eye-safe light source (1 to 6) according to Aspect 6 of the present invention may be configured such that in any one aspect of Aspects 1 to 5, a base material of a resin (scattering resin 352) that forms the lid (covers 150, 250, and 350) is of the same kind as a base material of the sealing resin (transparent resin layer 140; liquid state transparent resin 142).

According to the above configuration, since the base materials of the lid and the sealing resin are of the same kind, the lid and the sealing resin are easily fixed to each other, and engagement on the surface of contact between the lid and the sealing resin is reinforced.

An eye-safe light source (1, 2, 5, and 6) according to Aspect 7 of the present invention may be configured such that in any one aspect of Aspects 1 to 6, the lid (covers 150 and 250) includes an interlocking part (hook parts 158, 158a, and 158b) that interlocks with the sealing resin (transparent resin layer 140).

According to the above configuration, since the interlocking part causes the sealing resin and the lid to interlock with each other, engagement between the sealing resin and the lid is reinforced.

An eye-safe light source (1, 2, 5, and 6) according to Aspect 8 of the present invention may be configured such that in Aspect 7, the lid (covers 150 and 250) includes at least one first hole (resin filling holes 154, 154b, and 254; main exhaust hole 152m), and the interlocking part (hook parts 158, 158a, and 158b) is disposed in the first hole.

According to the above configuration, the interlocking part is disposed in the first hole. The container may be filled with the resin forming the sealing resin from the first hole, or air in the container may be discharged through the first hole. Thus, it is easy to design the interlocking part and manufacture the eye-safe light source such that a void does not remain around the interlocking part, and the interlocking part causes the sealing resin and the lid to interlock with each other.

An eye-safe light source (1, 2, 5, and 6) according to Aspect 9 of the present invention may be configured such that in any one aspect of Aspects 1 to 8, the lid (covers 150 and 250) includes at least one second hole (left exhaust holes 1521 and 2521; right exhaust holes 152r and 252r; main exhaust hole 152m), and at least some of air in the container (the recess parts 120, 220, and 320 disposed in the packages 108, 108a, 208, and 308) is discharged through the second hole.

According to the above configuration, air in the container is discharged from the second hole. Thus, the eye-safe light source is easily manufactured such that a void does not remain between the lid and the sealing resin and inside the sealing resin.

An eye-safe light source (1, 2, 5, and 6) according to Aspect 10 of the present invention may be configured such that in any one aspect of Aspects 1 to 9, the lid (covers 150 and 250) includes a fitting part (step parts 156 and 256) that fits in the opening (124 and 224).

According to the above configuration, since the fitting part causes the lid to fit in the opening of the container, a positional deviation of the lid from the container may be suppressed.

An eye-safe light source (3) according to Aspect 11 of the present invention may be configured such that in any one aspect of Aspects 1 to 6, the lid (cover 350) is disposed inside the container (the recess part 320 disposed in the package 308), and a first corner part (transparent resin corner part 144) that corresponds to a reference position (transparent resin reference position P1) on a boundary surface of the sealing resin (transparent resin layer 140) on an opening (324) side is disposed in the container.

According to the above configuration, the first corner part that corresponds to the reference position on the boundary surface of the sealing resin on the opening side is disposed in the container. Accordingly, when filling of the resin forming the sealing resin is performed, both creeping up of the resin along a side surface of the container beyond the reference position and overflowing of the resin beyond the reference position may be prevented. Therefore, an error in the filling amount of the sealing resin is reduced by the first corner part, and separation of the boundary surface from the reference position may be suppressed. In addition, the thickness of the lid formed on the sealing resin may be prevented from being non-uniform. Accordingly, variation in the light distribution characteristics and the eye safety of the eye-safe light source may be suppressed.

An eye-safe light source (3 and 4) according to Aspect 12 of the present invention may be configured such that in Aspect 11, a second corner part (scattering resin corner part 354) that corresponds to a reference position (scattering resin reference position P2) on a boundary surface of the lid (cover 350) on the opening (324) side is disposed in the container (the recess part 320 disposed in the package 308).

According to the above configuration, the second corner part that corresponds to the reference position on the boundary surface of the lid on the opening side is disposed in the container. Accordingly, when filling of the resin forming the lid is performed, both creeping up of the resin along a side surface of the container beyond the reference position and overflowing of the resin beyond the reference position may be prevented. Therefore, an error in the filling amount of the resin forming the lid is reduced by the second corner part, and separation of the boundary surface from the reference position may be suppressed. In addition, the thickness of the lid may be prevented from being non-uniform. Accordingly, variation in the light distribution characteristics and the eye safety of the eye-safe light source may be suppressed.

An eye-safe light source (1 to 6) according to Aspect 13 of the present invention may be configured such that in any one aspect of Aspects 1 to 12, the lid (covers 150, 250, and 350) scatters the laser light (114 and 214) further than the sealing resin (transparent resin layer 140).

According to the above configuration, since the sealing resin that resin-seals the semiconductor laser does not scatter the laser light much, the sealing resin may contain or may not contain a light scatterer. Approximately, as the content ratio of the light scatterer increases, the hardness of the resin increases, and a crack easily occurs. Therefore, according to the sealing resin that contains a small amount of light scatterer or does not contain a light scatterer, it is possible to suppress (i) an increase in defects of the semiconductor laser caused by stress from the sealing resin and a sudden turn-off of the semiconductor laser, (ii) a breakage of the wire joined to the semiconductor laser along with a crack in the sealing resin, and (iii) a local increase in temperature in the vicinity of a light emission end surface of the semiconductor laser caused by light absorption of the light scatterer included in the sealing resin and occurrence of catastrophic optical damage (COD) in the semiconductor laser.

In addition, according to the above configuration, since the lid that covers the opening of the container scatters the laser light, the laser light radiated from the opening is made eye-safe.

An eye-safe light source (1 to 6) according to Aspect 14 of the present invention may be configured such that in Aspect 13, the sealing resin (transparent resin layer 140; liquid state transparent resin 142) contains a light scatterer scattering the laser light at a first content weight percent of less than or equal to 2% with respect to a transparent resin that transmits the laser light (114 and 214) without scattering.

According to the above configuration, the sealing resin contains a sufficiently small amount of light scatterer or does not contain a light scatterer and thus, is flexible. Accordingly, it is possible to sufficiently suppress (i) an increase in defects of the semiconductor laser caused by stress from the sealing resin and a sudden turn-off of the semiconductor laser, (ii) a breakage of the wire joined to the semiconductor laser along with a crack in the sealing resin, and (iii) a local increase in temperature in the vicinity of the light emission end surface of the semiconductor laser caused by light absorption of the light scatterer included in the sealing resin and occurrence of catastrophic optical damage (COD) in the semiconductor laser.

An eye-safe light source (1 to 6) according to Aspect 15 of the present invention may be configured such that in Aspect 14, a resin (scattering resin 352) that forms the lid (covers 150, 250, and 350) contains the light scatterer scattering the laser light at a second content weight percent with respect to the transparent resin that transmits the laser light (114 and 214) without scattering, and the second content weight percent is higher than the first content weight percent.

According to the above configuration, it is possible to implement the lid that scatters the laser light further than the sealing resin.

An eye-safe light source (1 to 6) according to Aspect 16 of the present invention may be configured such that in any one aspect of Aspects 1 to 15, the semiconductor laser (100 and 200) is at least one of a green semiconductor laser, a red semiconductor laser, or an infrared semiconductor laser, and the reflective surface (116 and 216) of the container is a surface of a white resin.

According to the above configuration, since the semiconductor laser is at least one of a green semiconductor laser, a red semiconductor laser, or an infrared semiconductor laser, the laser light may be reflected on the surface of the white resin.

An eye-safe light source (1 to 6) according to Aspect 17 of the present invention may be configured such that in any one aspect of Aspects 1 to 15, the semiconductor laser (100 and 200) is at least one of a blue semiconductor laser, a green semiconductor laser, a red semiconductor laser, or an infrared semiconductor laser, and the reflective surface (116 and 216) of the container is a surface of metal.

According to the above configuration, since the reflective surface is a surface of metal, the laser light may be reflected even in a case where the semiconductor laser is a blue semiconductor laser.

An electronic device (optical sensor 7) according to Aspect 18 of the present invention may be configured to include the eye-safe light source according to any one aspect of Aspects 1 to 17.

According to the above configuration, an electronic device that includes the eye-safe light source according to the present invention may be implemented.

An electronic device (optical sensor 7) according to Aspect 19 of the present invention may be configured such that in Aspect 18, the electronic device is for biometric authentication.

According to the above configuration, an electronic device for biometric authentication that includes the eye-safe light source according to the present invention may be implemented.

A method (first manufacturing method) for manufacturing an eye-safe light source according to Aspect 20 of the present invention is a manufacturing method including a semiconductor laser mounting step of mounting a semiconductor laser (100) that emits laser light (114) on a bottom surface (123) of a container (the package 108 in which the recess part 120 is disposed) that includes a reflective surface (116) on which the laser light is reflected, and an opening (124) through which the reflected laser light is radiated; a lid mounting step of mounting a lid (cover 150) including a first hole (resin filling hole 154) on the container such that the lid covers at least part of the opening; a filling step of filling the container with a first resin (liquid state transparent resin 142) through the first hole until at least the first resin comes into contact with the lid; and a curing step of curing the first resin after filling, in which the cured first resin (transparent resin layer 140) fixes the lid to the container.

A method (second manufacturing method) for manufacturing an eye-safe light source according to Aspect 21 of the present invention is a manufacturing method including a semiconductor laser mounting step of mounting a semiconductor laser (100) that emits laser light (114) on a bottom surface (1233) of a container (the package 108 in which the recess part 120 is disposed) that includes a reflective surface (116) on which the laser light is reflected, and an opening (124) through which the reflected laser light is radiated; a filling step of filling the container with a first resin (liquid state transparent resin 142); a lid mounting step of mounting a lid (cover 150) such that the lid comes into contact with the first resin, and the lid covers at least part of the opening; and a curing step of curing the first resin in contact with the lid, in which the cured first resin (transparent resin layer 140) fixes the lid to the container.

A method (third manufacturing method) for manufacturing an eye-safe light source according to Aspect 22 of the present invention is a manufacturing method including a semiconductor laser mounting step of mounting a semiconductor laser (100) that emits laser light (114 and 214) on a bottom surface (123) of a container (the package 308 in which the recess part 320 is disposed) that includes a reflective surface (116) on which the laser light is reflected, and an opening (324) through which the reflected laser light is radiated; a filling step of filling the container with a first resin (liquid state transparent resin 142); a temporary curing step of temporarily curing the first resin after filling; a refilling step of further filling the container with a second resin (scattering resin 352) on the temporarily cured first resin (temporarily cured transparent resin 141); and a main curing step of curing the temporarily cured first resin and the second resin after filling at the same time, in which the cured second resin is a lid (cover 350) that covers at least part of the opening, and the cured first resin (transparent resin layer 140) fixes the lid to the container.

According to the manufacturing method according to Aspects 20 to 22, the lid is fixed to the container through the cured first resin in the container. Thus, at least part of a surface that is in contact with the cured first resin, that is, a region of the surface of the lid that faces the opening, contributes to the fixing of the lid to the container. Accordingly, the lid is not easily separated from the container, and a loss of eye safety caused by the separation of the lid from the eye-safe light source is prevented.

A method (first and second manufacturing methods) for manufacturing an eye-safe light source according to Aspect 23 of the present invention may be a manufacturing method in Aspect 20 or 21, in which the lid (cover 150) includes at least one second hole (left exhaust hole 1521; right exhaust hole 152r), and in the lid mounting step or the filling step, at least some of air in the container (the recess part 120 disposed in the package 108) is discharged through the second hole.

According to the above manufacturing method, air in the container is discharged through the second hole. Thus, the eye-safe light source is easily manufacturing such that a void does not remain in the container, and productivity may increase.

A method for manufacturing an eye-safe light source according to Aspect 24 of the present invention may be a manufacturing method in any one aspect of Aspects 20 to 23, in which the filling step includes a semiconductor laser sealing step of resin-sealing the semiconductor laser (100).

According to the above manufacturing method, the semiconductor laser may be resin-sealed at the same time as the fixing of the lid to the container. Accordingly, the eye-safe light source is easily manufactured, and productivity may increase.

A method for manufacturing an eye-safe light source according to Aspect 25 of the present invention may be a manufacturing method in any one aspect of Aspects 20 to 24, further including a connecting step of connecting a wire (110) to the semiconductor laser (100), in which the filling step includes a wire sealing step of resin-sealing the wire.

According to the above manufacturing method, the semiconductor laser may be resin-sealed at the same time as the fixing of the lid to the container. Accordingly, the eye-safe light source is easily manufactured, and productivity may increase.

The present invention is not limited to each embodiment described above, and various changes may be made within the scope disclosed in the claims. Embodiments that are acquired by appropriately combining technical means disclosed in each different embodiment also fall within the technical scope of the present invention. Furthermore, new technical features may be formed by combining technical means disclosed in each embodiment.

### REFERENCE SIGNS LIST

1 TO 6 EYE-SAFE LIGHT SOURCE
7 OPTICAL SENSOR
100, 200 SEMICONDUCTOR LASER
1001 LEFT LIGHT EMISSION END SURFACE
100r, 200r RIGHT LIGHT EMISSION END SURFACE
102 SUBMOUNT
104 LEAD FRAME
104a ANODE PART
104b CATHODE PART
106 RESIN PART
108, 108a, 208, 308 PACKAGE (CONTAINER)
110 WIRE
114, 214 LASER LIGHT
116, 216 REFLECTIVE SURFACE
118 OPTICAL AXIS
120, 220, 320 RECESS PART
122 EXPOSED PART
123 BOTTOM SURFACE
124, 224 OPENING
140 TRANSPARENT RESIN LAYER (SEALING RESIN; CURED FIRST RESIN)
140a FIRST REGION
140b SECOND REGION
141 TEMPORARILY CURED TRANSPARENT RESIN (TEMPORARILY CURED FIRST RESIN)
142 LIQUID STATE TRANSPARENT RESIN (FIRST RESIN)
144 TRANSPARENT RESIN CORNER PART (FIRST CORNER PART)
150, 150a, 150b, 250, 350 COVER (LID; CURED SECOND RESIN)
1521, 2521 LEFT EXHAUST HOLE (SECOND HOLE)
152m MAIN EXHAUST HOLE (SECOND HOLE)
152r, 252r RIGHT EXHAUST HOLE (SECOND HOLE)
154, 154b, 254 RESIN FILLING HOLE (FIRST HOLE)
156, 256 STEP PART (FITTING PART)
157, 257 PERIPHERAL PART
158, 158a, 158b HOOK PART (INTERLOCKING PART)
352 SCATTERING RESIN (SECOND RESIN)
354 SCATTERING RESIN CORNER PART (SECOND CORNER PART)
732 LIGHT RECEIVING UNIT
734 CONTROL UNIT
P1 TRANSPARENT RESIN REFERENCE POSITION (REFERENCE POSITION ON BOUNDARY SURFACE OF SEALING RESIN ON OPENING SIDE)
P2 SCATTERING RESIN REFERENCE POSITION (REFERENCE POSITION ON BOUNDARY SURFACE OF LID ON OPENING SIDE)
S CAVITY

1. An eye-safe light source comprising:
a semiconductor laser that emits laser light;
a container that includes a bottom surface on which the semiconductor laser is mounted, a reflective surface on which the laser light is reflected, and an opening through which the reflected laser light is radiated;
a lid that covers at least part of the opening; and
a sealing resin that is disposed in the container, seals the semiconductor laser, and fixes the lid to the container.

2. The eye-safe light source according to claim 1,
wherein the lid scatters the laser light and is disposed on at least an optical path of the laser light in the opening.

3. The eye-safe light source according to claim 1,
wherein the lid includes an interlocking part that interlocks with the sealing resin.

4. The eye-safe light source according to claim 3,
wherein the lid includes at least one first hole, and
the interlocking part is disposed in the first hole.

5. The eye-safe light source according to claim 1,
wherein the lid includes at least one second hole, and
at least some of air in the container is discharged through the second hole.

6. The eye-safe light source according to claim 1,
wherein the lid includes a fitting part that fits in the opening.

7. The eye-safe light source according to claim 1,
wherein the lid is disposed inside the container, and
a first corner part that corresponds to a reference position on a boundary surface of the sealing resin on a side of the opening is disposed in the container.

8. The eye-safe light source according to claim 7,
wherein a second corner part that corresponds to a reference position on a boundary surface of the lid on a side of the opening is disposed in the container.

9. A method for manufacturing an eye-safe light source, comprising:
a semiconductor laser mounting step of mounting a semiconductor laser that emits laser light on a bottom surface of a container that includes a reflective surface on which the laser light is reflected, and an opening through which the reflected laser light is radiated;
a lid mounting step of mounting a lid including a first hole on the container such that the lid covers at least part of the opening;
a filling step of filling the container with a first resin through the first hole until at least the first resin comes into contact with the lid; and
a curing step of curing the first resin after filling,
wherein the cured first resin fixes the lid to the container.

10. A method for manufacturing an eye-safe light source, comprising:
a semiconductor laser mounting step of mounting a semiconductor laser that emits laser light on a bottom surface of a container that includes a reflective surface on which the laser light is reflected, and an opening through which the reflected laser light is radiated;
a filling step of filling the container with a first resin;
a lid mounting step of mounting a lid such that the lid comes into contact with the first resin, and the lid covers at least part of the opening; and
a curing step of curing the first resin in contact with the lid,
wherein the cured first resin fixes the lid to the container.

11. A method for manufacturing an eye-safe light source, comprising:
a semiconductor laser mounting step of mounting a semiconductor laser that emits laser light on a bottom surface of a container that includes a reflective surface on which the laser light is reflected, and an opening through which the reflected laser light is radiated;
a filling step of filling the container with a first resin;
a temporary curing step of temporarily curing the first resin after filling;
a refilling step of further filling the container with a second resin on the temporarily cured first resin; and
a main curing step of curing the temporarily cured first resin and the second resin after filling at the same time,
wherein the cured second resin is a lid that covers at least part of the opening, and
the cured first resin fixes the lid to the container.
